(19) United States
(12) Patent Application Publication
(10) Pub. No.: US 2024/0387269 A1
(43) Pub. Date: Nov. 21, 2024

(54) INTEGRATED CIRCUIT STRUCTURE AND METHOD FOR FABRICATING THE SAME

(71) Applicant: TAIWAN SEMICONDUCTOR MANUFACTURING COMPANY, LTD., Hsinchu (TW)

(72) Inventors: Yu-Hsin CHAN, Hsinchu City (TW); Chang-Wen CHEN, Hsinchu City (TW)

(73) Assignee: TAIWAN SEMICONDUCTOR MANUFACTURING COMPANY, LTD., Hsinchu (TW)

(21) Appl. No.: 18/318,865

(22) Filed: May 17, 2023

(51) Int. Cl. H01L 21/768; H01L 21/8238; H01L 23/48; H01L 27/092

(52) U.S. Cl. CPC H01L 21/76898; H01L 21/823842; H01L 21/823878; H01L 23/481; H01L 27/092

(57) ABSTRACT

A method for fabricating an integrated circuit structure is provided. The method includes forming a gate structure over a semiconductor substrate; forming a source/drain epitaxial structure adjacent a side of the gate structure; forming a first isolation structure in the gate structure, wherein the first isolation structure spaces apart a first portion of the gate structure from a second portion of the gate structure; forming a front-side metallization layer over a frontside of the semiconductor substrate, wherein the front-side metallization layer comprises a front-side metal feature overlapping the first isolation structure; depositing a dielectric layer over a backside of the semiconductor substrate; forming a conductive via in the dielectric layer and the first isolation structure, wherein the conductive via is in contact with a backside of the front-side metal feature.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET), including a gate-all-around (GAA) FET. In a GAA FET, all side surfaces of the channel region are surrounded by the gate electrode, which allows for fuller depletion in the channel region and results in less short-channel effects due to steeper sub-threshold current swing (SS) and smaller drain induced barrier lowering (DIBL).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8D illustrate intermediate stages of a method for fabricating an integrated circuit structure in accordance with some embodiments of the present disclosure.

FIGS. 9A-24 illustrate intermediate stages of a method for fabricating an integrated circuit structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

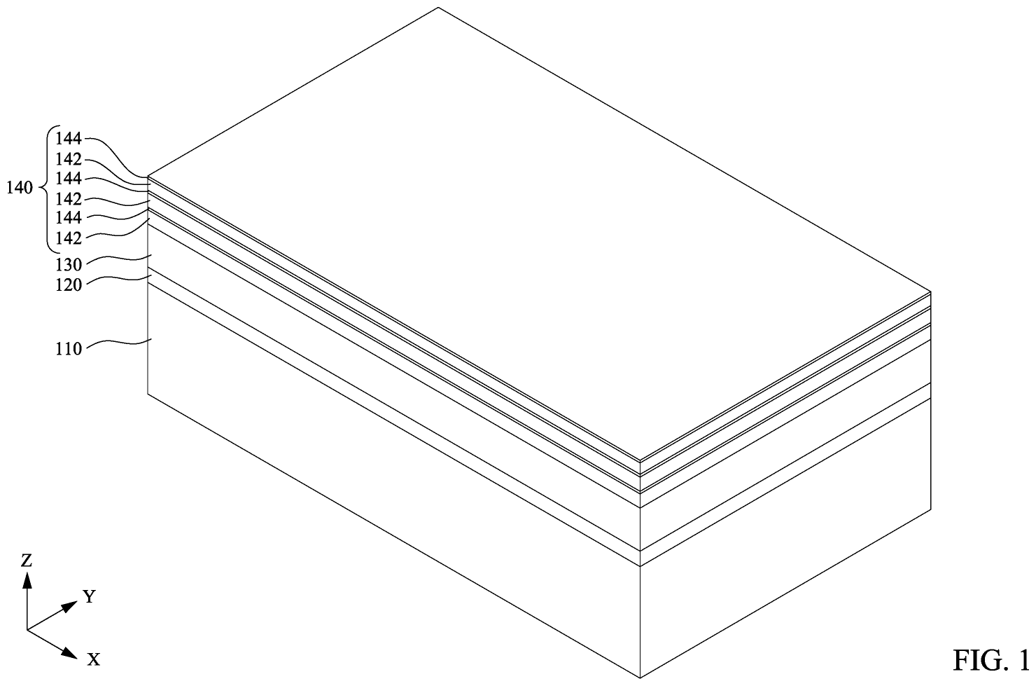

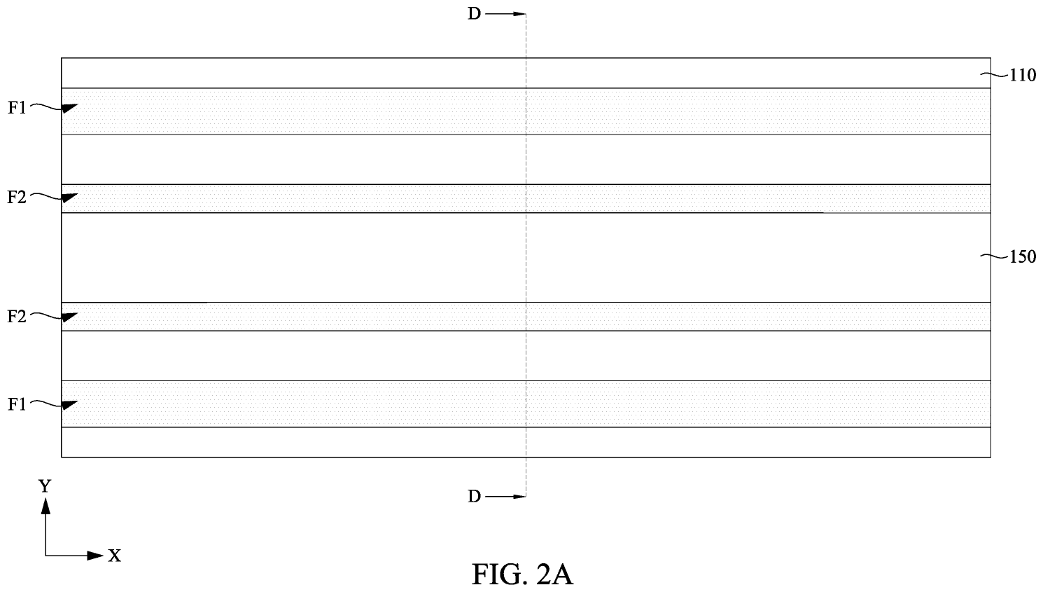

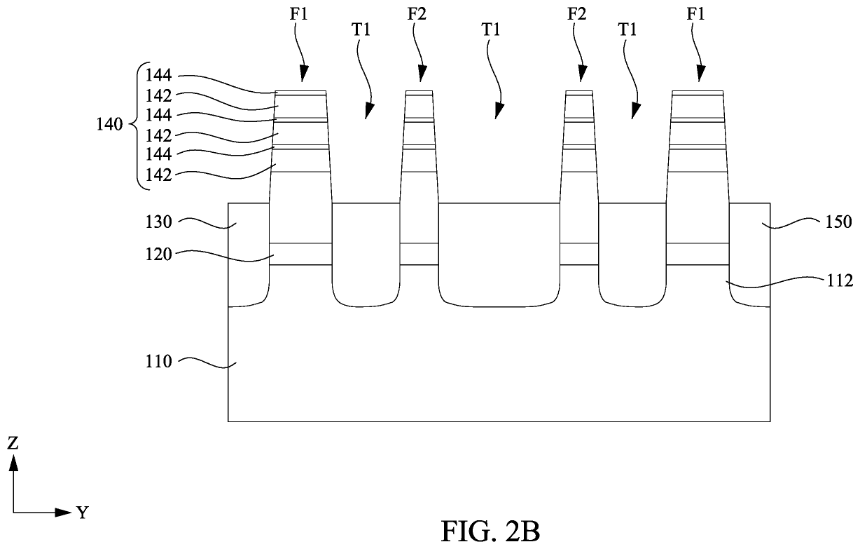

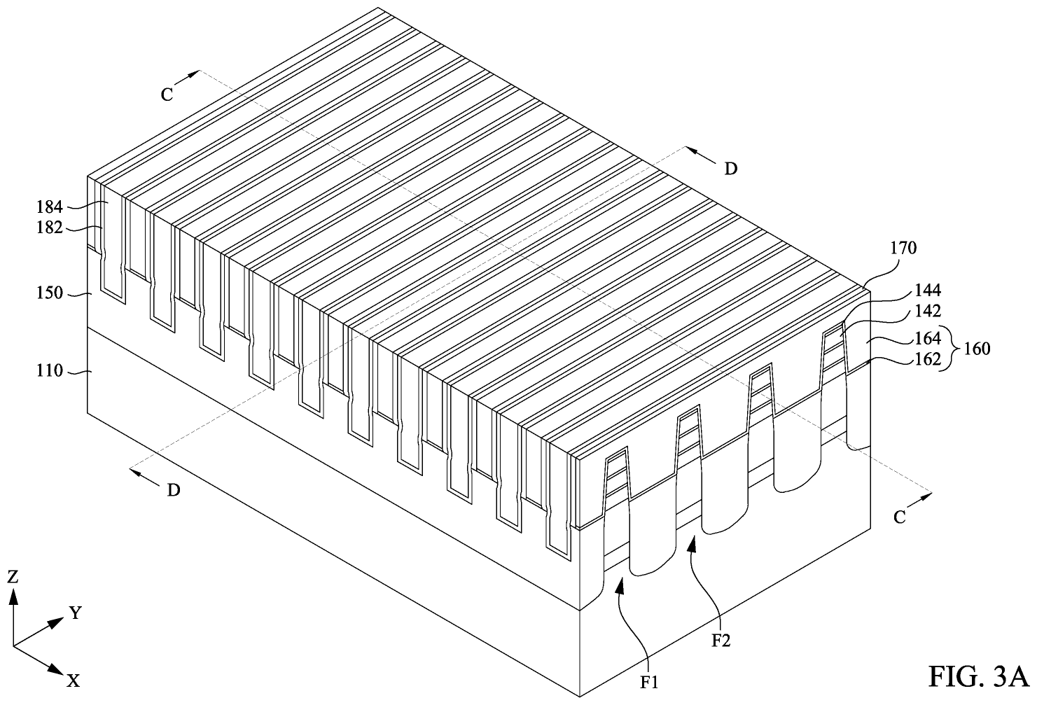

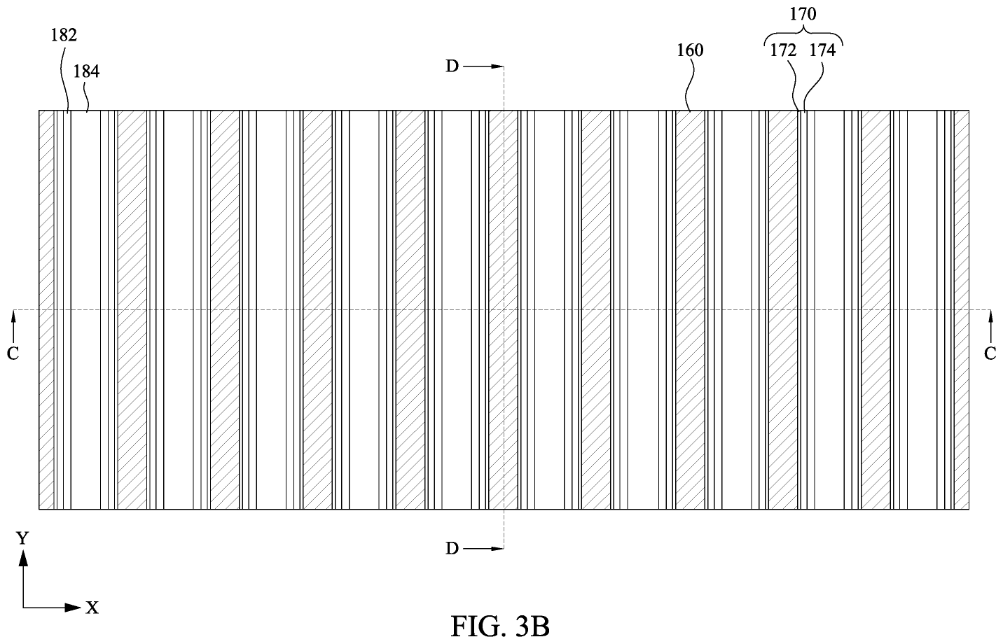

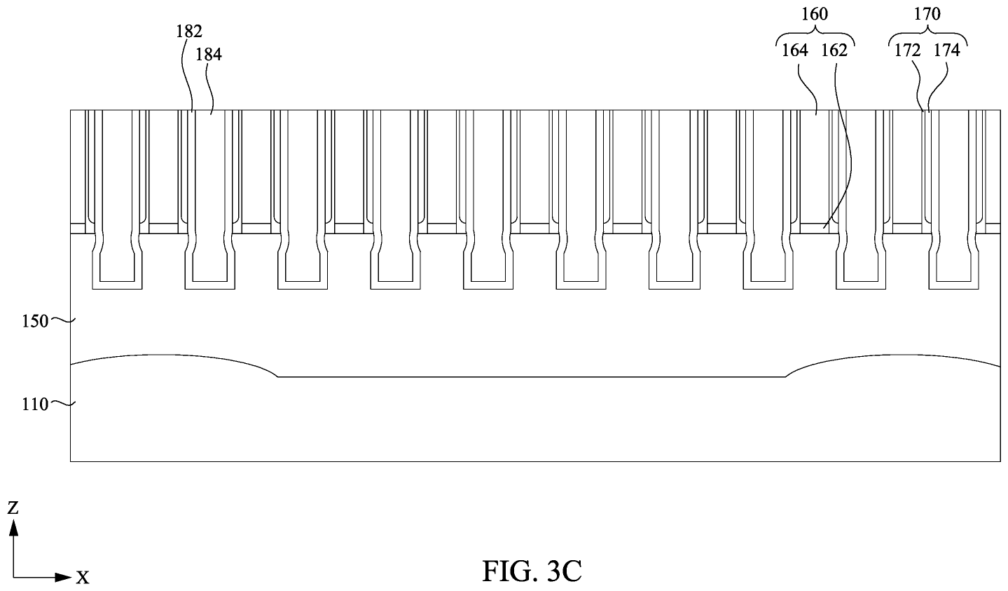

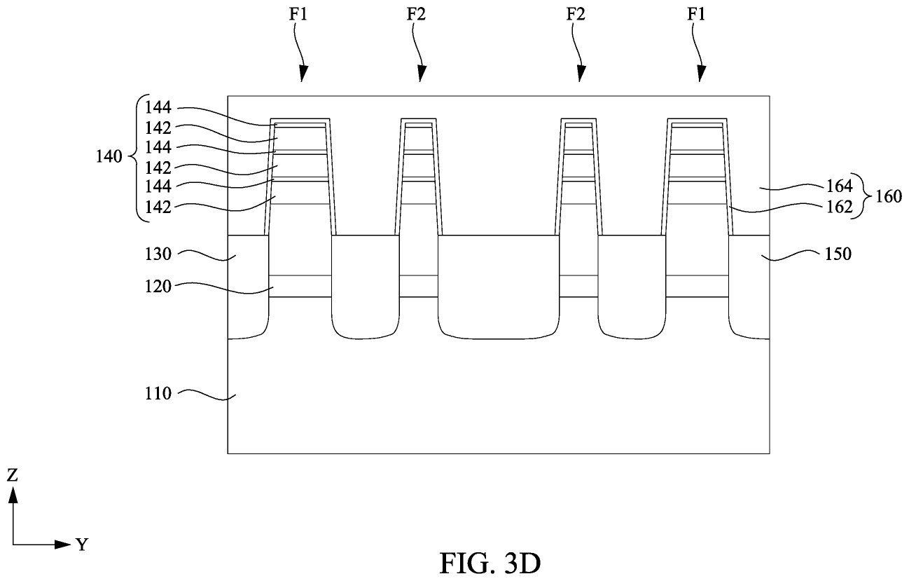

FIGS. 1-8D illustrate intermediate stages of a method for fabricating an integrated circuit structure in accordance with some embodiments of the present disclosure. FIGS. 1, 3A, 4A, 5A, and 8A are perspective views of the integrated circuit structure. FIGS. 2A, 3B, 4B, 5B, and 8B are top views of the integrated circuit structure. FIGS. 3C, 4C, 5C, 6A, 7A, and 8C are cross-sectional views of the integrated circuit structure taken along first cuts (e.g., cuts C-C in FIGS. 3B, 4B, 5B, and 8B). FIGS. 2B, 3D, 4D, 5D, 6B, 7B, and 8D are cross-sectional views of the integrated circuit structure taken along second cuts (e.g., cuts D-D in FIGS. 2A, 3B, 4B, 5B, and 8B). It is understood that additional operations may be provided before, during, and after the operations shown by FIGS. 1-8D, and some of the operations described below can be replaced or eliminated for additional embodiments of the method. The order of the operations/processes may be interchangeable.

FIG. 1 shows an initial structure. The initial structure includes a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer.

In some embodiments, a semiconductive etch stop layer 120 and a semiconductive layer 130 may be formed over the substrate 110 by suitable epitaxial growth process. The semiconductive layer 130 may include a semiconductor composition the same as that of the substrate 110. The semiconductive etch stop layer 120 may include a semiconductor composition different from the semiconductive layer 130 and the substrate 110. For example, the semiconductive etch stop layer 120 is SiGe, and the substrate 110 and the semiconductive layer 130 includes silicon (Si).

An epitaxial stack 140 is formed over the semiconductive layer 130. The epitaxial stack 140 includes epitaxial layers 142 of a first composition interposed by epitaxial layers 144 of a second composition. The first and second compositions can be different. In some embodiments, the epitaxial layers 142 are SiGe, and the epitaxial layers 144 are silicon (Si). However, other embodiments are possible including those that provide for a first composition and a second composition having different oxidation rates and/or etch selectivity. In some embodiments where the epitaxial layers 142 include SiGe and the epitaxial layers 144 include Si, the Si oxidation rate of the epitaxial layers 144 is less than the SiGe oxidation rate of the epitaxial layers 142.

The epitaxial layers 144 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 144 to define a channel or channels of a device is further discussed below. It is noted that three layers of the epitaxial layers 142 and three layers of the epitaxial layers 144 are alternately arranged as illustrated in FIG. 1. It can be appreciated that any number of epitaxial layers can be formed in the epitaxial stack 140; the number of layers depending on the desired number of channels regions for the transistor. In some embodiments, the number of epitaxial layers 144 is between 2 and 10.

In some embodiments, the epitaxial layers 142 may be substantially uniform in thickness, and the epitaxial layers 144 of the stack are substantially uniform in thickness. As described in more detail below, the epitaxial layers 144 may serve as channel region(s) for a subsequently-formed multi-gate device and the thickness is chosen based on device performance considerations. The epitaxial layers 142 in channel regions(s) may eventually be removed and serve to define a vertical distance between adjacent channel region(s) for a subsequently-formed multi-gate device and the thickness is chosen based on device performance considerations. Accordingly, the epitaxial layers 142 may also be referred to as sacrificial layers, and epitaxial layers 144 may also be referred to as channel layers.

By way of example, epitaxial growth of the layers of the stack 140 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 144 include the same material as the substrate 110. In some embodiments, the epitaxially grown layers 142 and 144 include a different material than the substrate 110. As stated above, in at least some examples, the epitaxial layers 142 include an epitaxially grown silicon germanium (SiGe) layer and the epitaxial layers 144 include an epitaxially grown silicon (Si) layer. Alternatively, in some embodiments, either of the epitaxial layers 142 and 144 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 142 and 144 may be chosen based on providing differing oxidation and/or etching selectivity properties. In some embodiments, the epitaxial layers 142 and 144 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A and 2B. The semiconductive etch stop layer 120, the semiconductive layer 130, and the epitaxial stack 140 are patterned, thereby forming plural fins F1 and F2. For example, the suitable masks are first formed to protect regions of the substrate 110, while etch processes are performed to form trenches T1 in unprotected regions through the semiconductive etch stop layer 120, the semiconductive layer 130, and the epitaxial stack 140, and into the substrate 110, thereby leaving the plurality of extending fins F1 and F2. The trenches T1 may be etched using a dry etch (e.g., reactive ion etching), a wet etch, and/or combination thereof. In some embodiments, the fins F1 are active fins that include channels for transistors, and the fins F2 are dummy fins that include no channels for transistors. A width of the fins F2 may be different from a width of the fins F1. For example, the width of the fins F2 is less than a width of the fins F1.

In some alternative embodiments, the fins F1 and F2 may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins F1 and F2 by etching initial epitaxial stack 140. The etching process can include dry etching, wet etching, reactive ion etching (RIE), and/or other suitable processes.

Numerous other embodiments of methods to form the fins on the substrate may also be used including, for example, defining the fin region (e.g., by mask or isolation regions) and epitaxially growing the epitaxial stack 140 in the form of the fins F1 and F2. In various embodiments, each of the fins F1 and F2 includes a base portion 112 patterned from the semiconductor substrate 110 and portions of each of the epitaxial layers 142 and 144 of the epitaxial stack 140.

Shallow trench isolation (STI) structures 150 are formed in the trenches T1 between the fins F1 and F2. By way of example and not limitation, a dielectric layer is first deposited over the substrate 110, filling the trenches Tl with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. After deposition of the dielectric layer, the deposited dielectric material is thinned and planarized, for example by a chemical mechanical polishing (CMP) process. Remaining portions of the dielectric layer form the STI structures 150. Next, the STI structures 150 are recessed in an etch back process, such that the fins F1 and F2 has exposed sidewall extending above the STI structure 150. In some embodiments, the recessing process may include a dry etching process, a wet etching process, and/or a combination thereof. In some embodiments, a recessing depth is controlled (e.g., by controlling an etching time) so as to result in a target height of the exposed upper portion of the fins F1 and F2. In the illustrated embodiments, the target height exposes each of the epitaxial layers 142 and 144 of the epitaxial stack 140 in the fins F1 and F2.

Reference is made to FIGS. 3A-3D. Dummy gate structures 160 are formed. In some embodiments, the dummy gate structures 160 each include the dummy gate dielectric layer 162 and a dummy gate electrode layer 164. In some embodiments, the dummy gate structures 160 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the dummy gate dielectric layer 162 may include silicon oxide. In some embodiments, the dummy gate electrode layer 164 may include polycrystalline silicon (polysilicon).

In some embodiments, gate spacers 170 are formed on sidewalls of the dummy gate structures 160. In some embodiments of formation of the gate spacers 170, a spacer material layer is first deposited over the substrate 110. The spacer material layer may be a conformal layer that is subsequently etched to form gate sidewall spacers on sidewalls of the dummy gate structures 160. In some embodiments, the spacer material layer includes multiple layers, such as a first spacer layer 172 and a second spacer layer 174 formed over the first spacer layer 172. The gate spacers 170 may include a dielectric material such as silicon oxide, silicon nitride, silicon oxynitride, SiCN films, silicon oxycarbide, SiOCN films, and/or combinations thereof.

An etch stop layer (ESL) 182 and an interlayer dielectric (ILD) layer 184 are formed. In some examples, the ESL 182 includes a silicon nitride layer, silicon oxide layer, a silicon oxynitride layer, and/or other suitable materials. The ESL 182 may be formed by plasma-enhanced chemical vapor deposition (PECVD) process and/or other suitable deposition or oxidation processes. In some embodiments, the ILD layer 184 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL 182. The ILD layer 184 may be deposited by a CVD process or other suitable deposition technique.

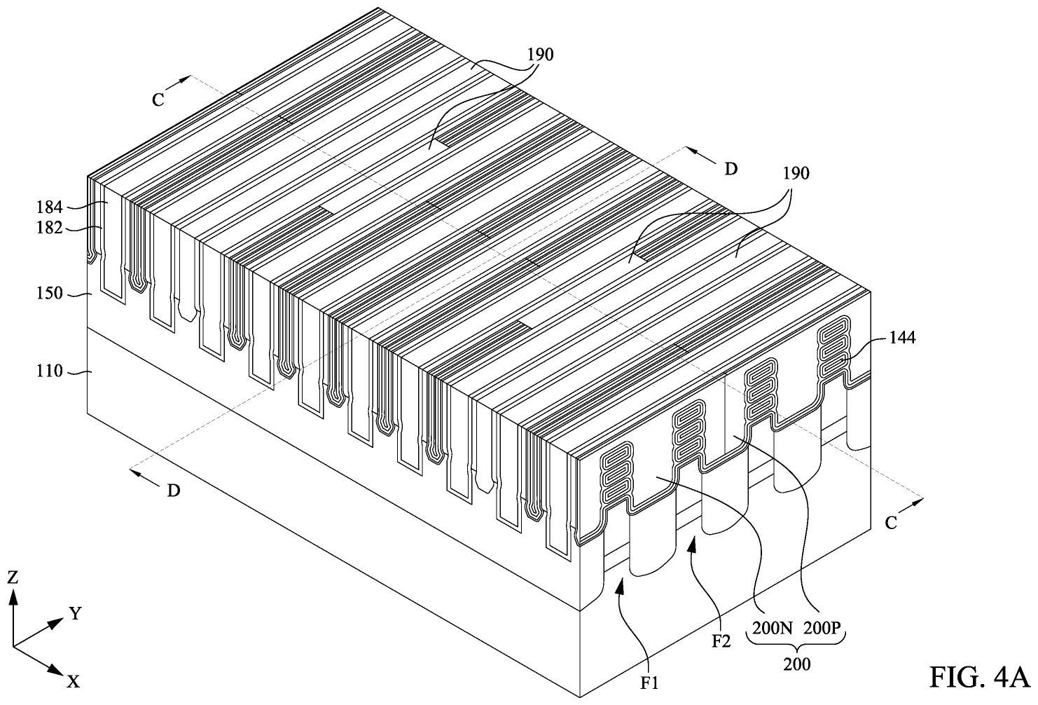

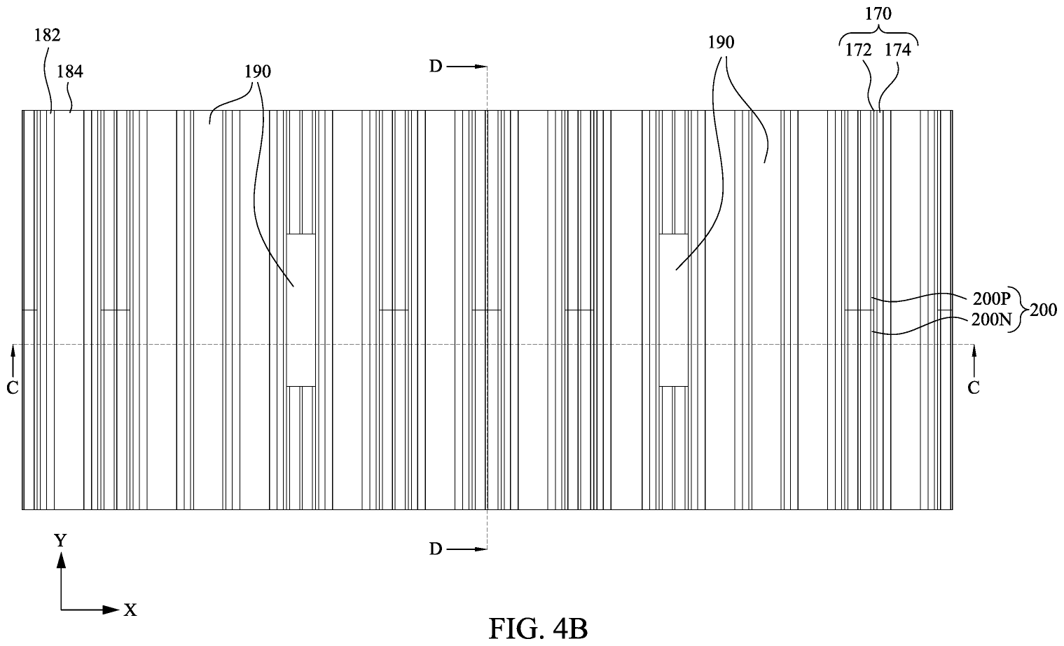

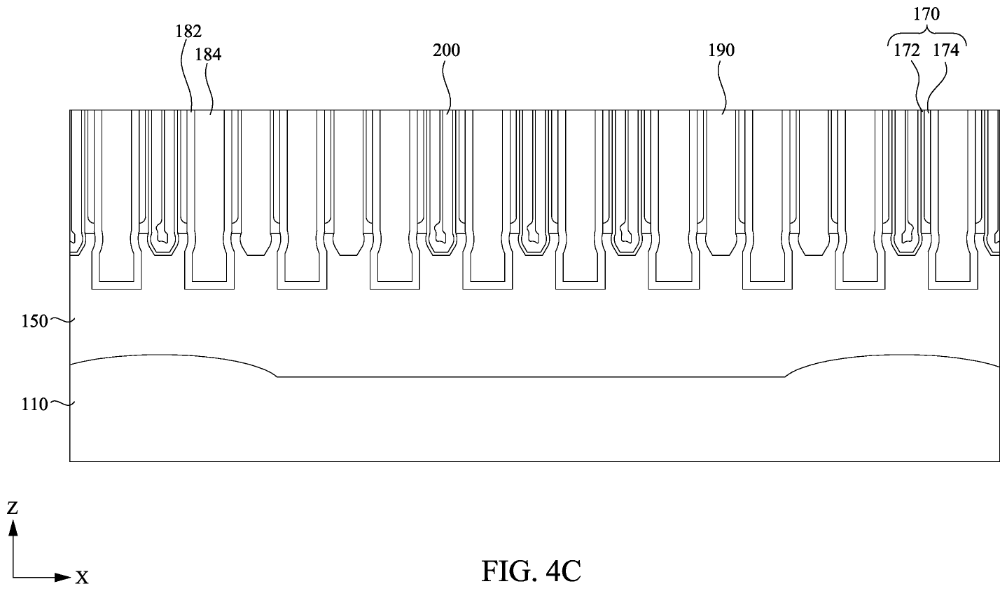

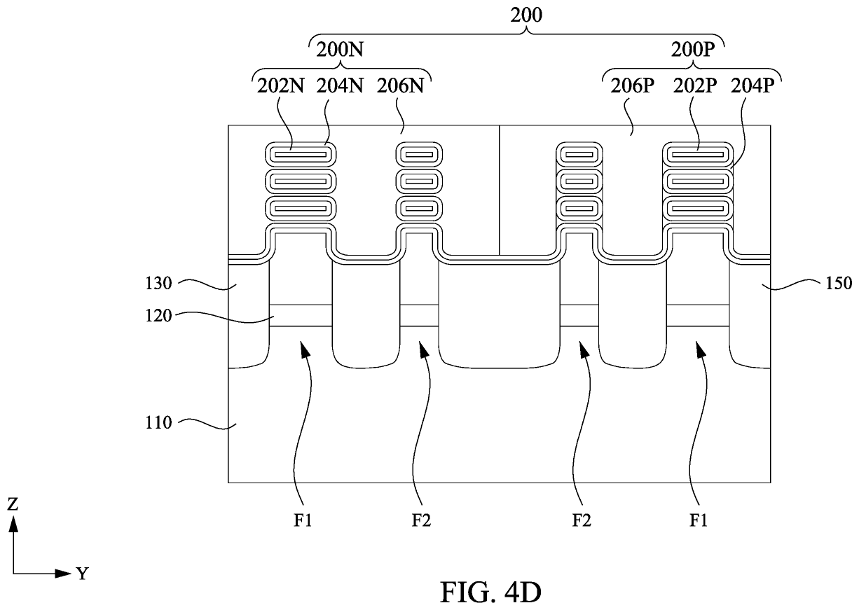

Reference is made to FIGS. 4A-4D. The dummy gate structures 160 and the underlying sacrificial layers 142 (referring to FIGS. 3A-3D) are replaced with high-k/metal gate structures 200. The dummy gate structures 160 (referring to FIGS. 3A-3D) are removed, followed by removing the sacrificial layers 142 (referring to FIGS. 3A-3D). For example, the dummy gate structures 160 (referring to FIGS. 3A-3D) are removed by using a selective etching process (e.g., selective dry etching, selective wet etching, or a combination thereof) that etches the materials in dummy gate structures 160 (referring to FIGS. 3A-3D) at a faster etch rate than it etches other materials (e.g., the gate spacers 170, the ESL 182, and/or the ILD layer 184), thus resulting in gate trenches between corresponding gate spacers 170, with the sacrificial layers 142 (referring to FIGS. 3A and 3D) exposed in the gate trenches. Subsequently, the sacrificial layers 142 (referring to FIGS. 3A and 3D) in the gate trenches are etched by using another selective etching process that etches the sacrificial layers 142 at a faster etch rate than it etches the layers 144 and 130, thus forming openings/spaces between neighboring layers 144 and 130. In this way, the channel layers 144 become nanosheets suspended over the substrate 110. This step is also called a channel release process. At this interim processing step, the openings/spaces surrounding the nanosheets 144 may be filled with ambient environment conditions (e.g., air, nitrogen, etc). In some embodiments, the nanosheets 144 can be interchangeably referred to as nanowires, nanoslabs and nanorings, depending on their geometry. For example, in some other embodiments, the channel layers 144 may be trimmed to have a substantial rounded shape (i.e., cylindrical) due to the selective etching process for completely removing the sacrificial layers 142 (referring to FIGS. 3A and 3D). In that case, the resultant channel layers 144 can be called nanowires.

In some embodiments, the sacrificial layers 142 (referring to FIGS. 3A and 3D) are removed by using a selective dry etching process. In some embodiments, the sacrificial layers 142 (referring to FIGS. 3A and 3D) are SiGe and the channel layers 144 are silicon allowing for the selective removal of the sacrificial layers 142 (referring to FIGS. 3A and 3D). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 142 (referring to FIGS. 3A and 3D) are removed. Moreover, because oxidation rate of Si is much lower (sometimes 30 times lower) than oxidation rate of SiGe, the channel layers 144 and the semiconductive layer 130 may remain substantially intact during the channel release process.

Replacement gate structures 200 are then respectively formed in the gate trenches to surround each of the nanosheets 144 suspended in the gate trenches. The gate structures 200 may be final gates of GAA FETs. The final gate structure may be a high-k/metal gate stack, however other compositions are possible. In some embodiments, each of the gate structures 200 forms the gate associated with the multi-channels provided by the plurality of nanosheets 144. For example, the high-k/metal gate structures 200 are formed within the openings/spaces provided by the release of nanosheets 144. The high-k/metal gate structures 200 may be between the layers 144 and 130.

The high-k/metal gate structure 200 includes a high-k/metal gate structure 200N for n-type device and a high-k/metal gate structure 200P for p-type device. In various embodiments, the high-k/metal gate structure 200N/200P includes a gate dielectric layer 202N/202P formed around the nanosheets 144, a work function metal stack layer 204N/204P formed around the gate dielectric layer 202N/202P, and a fill metal 206N/206P formed around the work function metal layer 204N/204P and filling a remainder of the gate trenches. Formation of the high-k/metal gate structures 200N/200P may include one or more deposition processes to form various gate materials, followed by a CMP processes to remove excessive gate materials, resulting in the high-k/metal gate structures 200N/200P having top surfaces level with a top surface of the ILD layer 184. Thus, transistors (e.g., GAA FET) are formed, and the high-k/metal gate structure 200N/200P surrounds each of the nanosheets 144, and thus is referred to as a gate of the transistors (e.g., GAA FET).

The gate dielectric layer 202N/202P may include an interfacial layer and a high-k gate dielectric layer over the interfacial layer. In some embodiments, the interfacial layer is silicon oxide formed on exposed surfaces of semiconductor materials in the gate trenches by using, for example, thermal oxidation, chemical oxidation, wet oxidation or the like. As a result, surface portions of the layers 144 and 130 exposed in the gate trenches are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the work function metal stack layer 204N/204P may include one or more work function metal layers stacked one over another. The one or more work function metal layers in the work function metal stack layer 204N/204P provide a suitable work function for the high-k/metal gate structures 200N/200P. For an n-type GAA FET, the work function metal stack layer 204N may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AlC)), aluminides, titanium nitride (TiN), tungsten (W), and/or other suitable materials. On the other hand, for a p-type GAA FET, the work function metal stack layer 204P may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal 206N/206P may exemplarily include, but are not limited to, tungsten, aluminum, copper, nickel, cobalt, titanium, tantalum, titanium nitride, tantalum nitride, nickel silicide, cobalt silicide, TaC. TaSiN, TaCN, TiAl, TiAIN, or other suitable materials.

After the gate replacement process, plural isolation structures 190 are formed for cutting the fins F1 and F2. For example, a first portion of the dummy gate structures 160 (referring to FIGS. 3A-3D) are replaced with the high-k/metal gate structures 200, leaving a second portion of the dummy gate structures 160 (referring to FIGS. 3A-3D) not replaced with the high-k/metal gate structures 200. Then, the second portion of the dummy gate structures 160 (referring to FIGS. 3A-3D) are removed, and then a trench is etched in the underlying portion of the epitaxial stack 140 to cut one fin F1/F2 into two separate fins. Then, a dielectric layer (e.g., silicon nitride) is deposited over the substrate 110, filling the trenches in the portion of the epitaxial stack 140, thereby forming the isolation structures 190 between the separate fins. The dielectric layer for the isolation structures 190 may include silicon nitride, silicon oxynitride, silicon carbide, the like, or the combination thereof. The isolation structures 190 may have bottoms in contact with the STI structures 150.

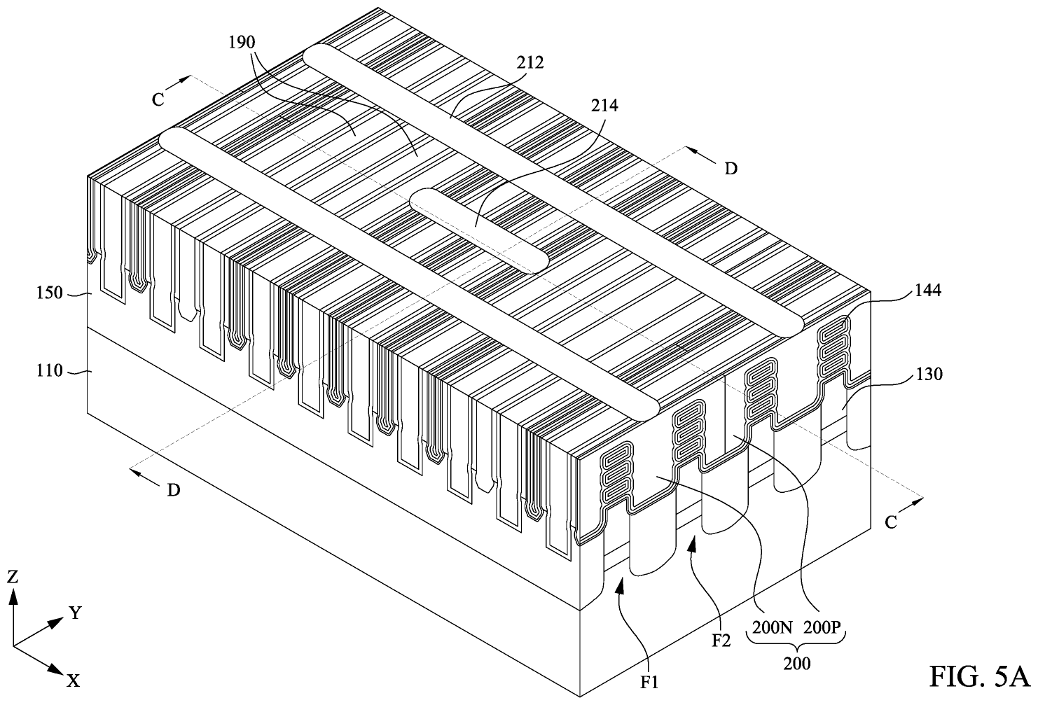

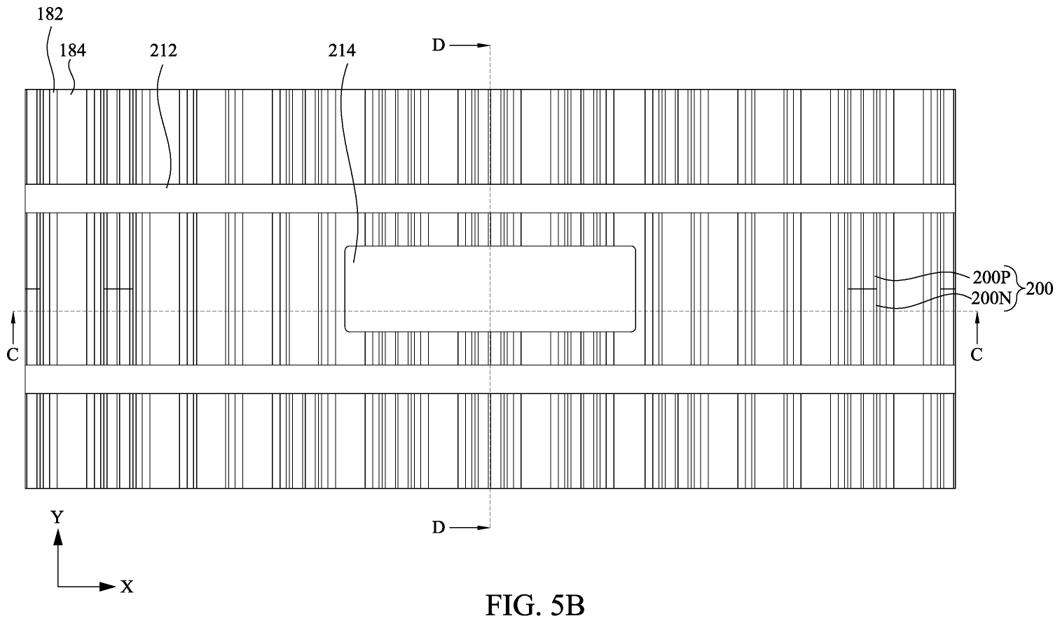

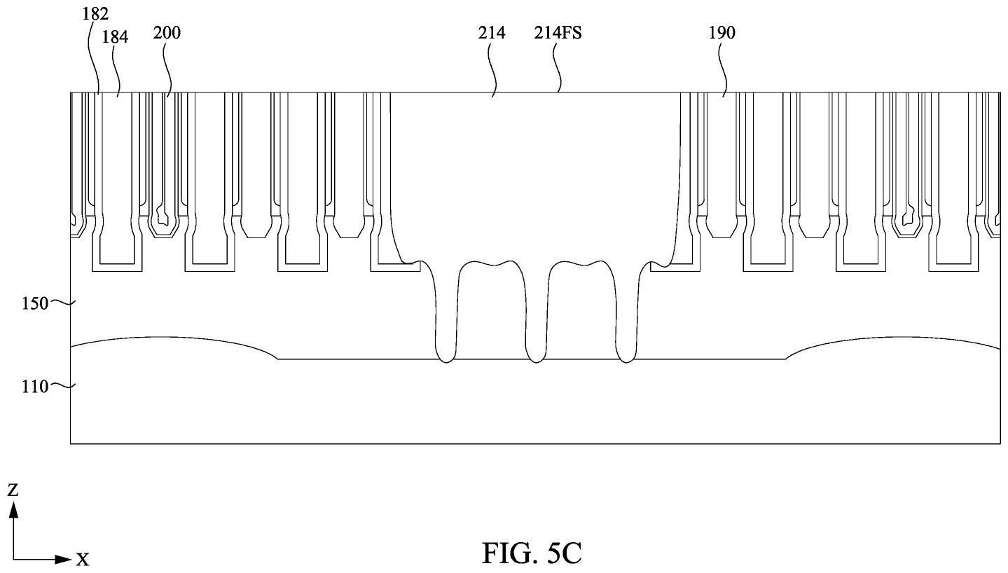

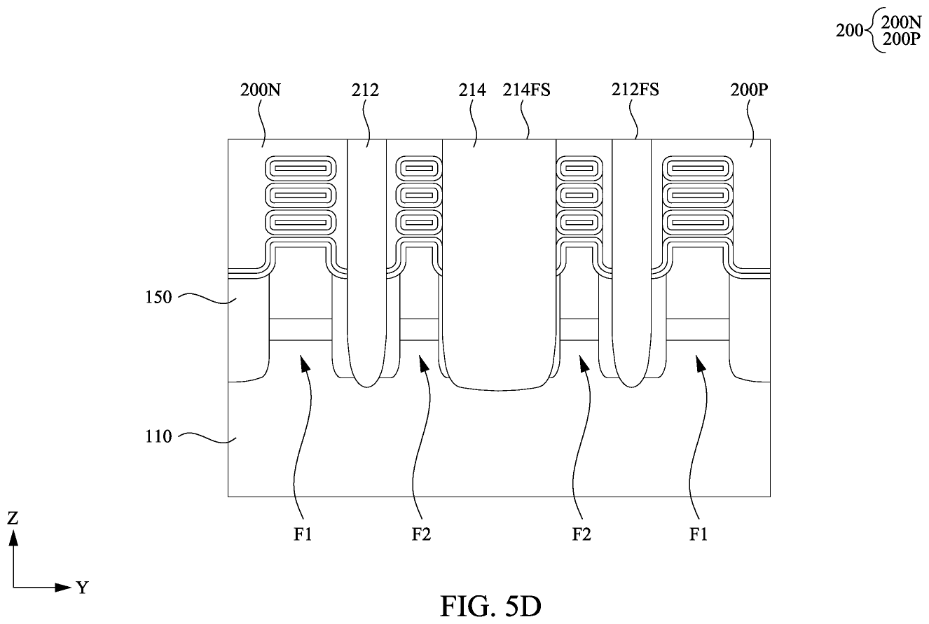

Reference is made to FIGS. 5A-5D. Plural isolation structures 212 and 214 are formed for cutting the high-k/metal gate structure 200 into separate high-k/metal gate structures. For example, each of the isolation structures 212 and 214 spaces a portion of the high-k/metal gate structure 200 from another portion of the high-k/metal gate structure 200. The isolation structures 212 and 214 may be referred to as “cut-metal-gate” (CMG) structures. Trenches are etched in the high-k/metal gate structure 200, the ILD layer 184, and the STI structures 150 by suitable lithography process and etching process. Then, a dielectric layer is deposited over the substrate 110, filling the trenches, follow by a CMP process to remove excess portions of the dielectric layer. The remain portions of the dielectric layer in the trenches form the isolation structures 212 and 214 between the separate high-k/metal gate structures. The dielectric layer for the isolation structures 212 and 214 may include silicon nitride, silicon oxynitride, silicon carbide, the like, or the combination thereof. For example, one of the isolation structures 212 may space a high-k/metal gate structure with an n-type work function metal from another high-k/metal gate structure with an n-type work function metal, while another of the isolation structures 212 may space a high-k/metal gate structure with an p-type work function metal from another high-k/metal gate structure with an p-type work function metal. And, the isolation structure 214 may space a high-k/metal gate structure with an n-type work function metal from a high-k/metal gate structure with an p-type work function metal. By the CMP process, the frontsides 212FS and 214FS of the isolation structures 212 and 214 are exposed. In some embodiments, the isolation structure 212 is between the adjacent fins F1 and F2, and the isolation structure 214 is between the adjacent fins F2. The isolation structures 212 and 214 may extend through the STI structures 150. A bottom surface of the isolation structures 212 and 214 may be level with or lower than a bottom surface of the STI structures 150.

In some embodiments, the isolation structure 214 may have a profile different from the isolation structure 212. For example, a length of the isolation structure 212 along a direction perpendicular to the lengthwise direction of the gate structure 200 is greater than a length of the isolation structure 214 along the direction from a top view. And, a width of the isolation structure 212 along a lengthwise direction of the gate structure 200 may be less than a width of the isolation structure 214 along the lengthwise direction of the gate structure 200 from a top view.

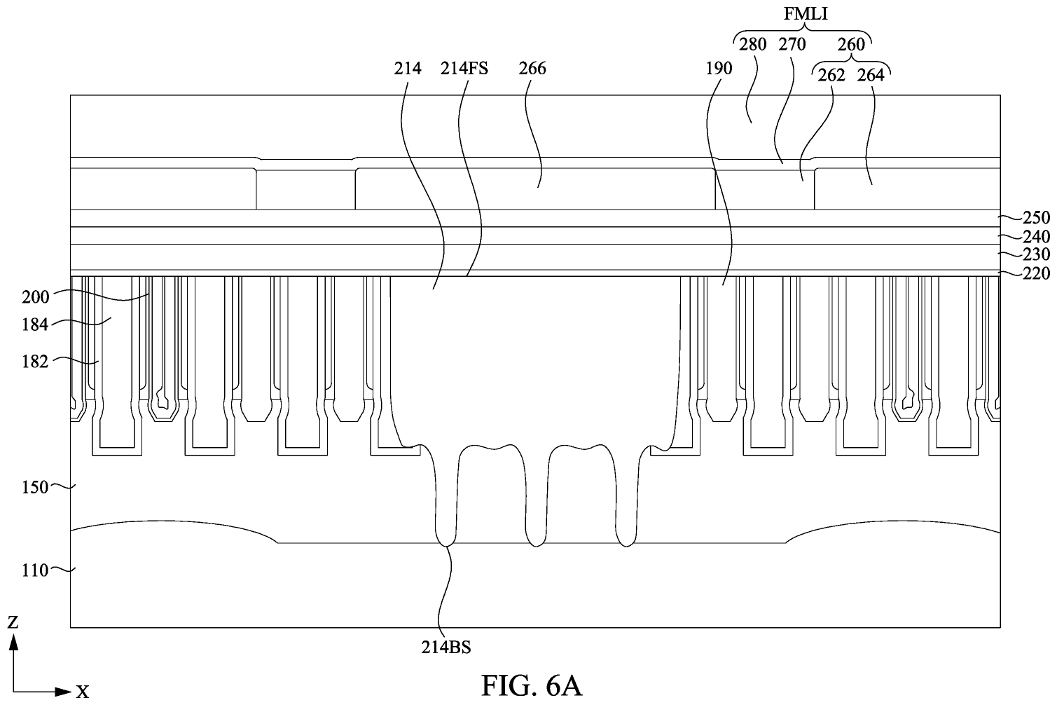

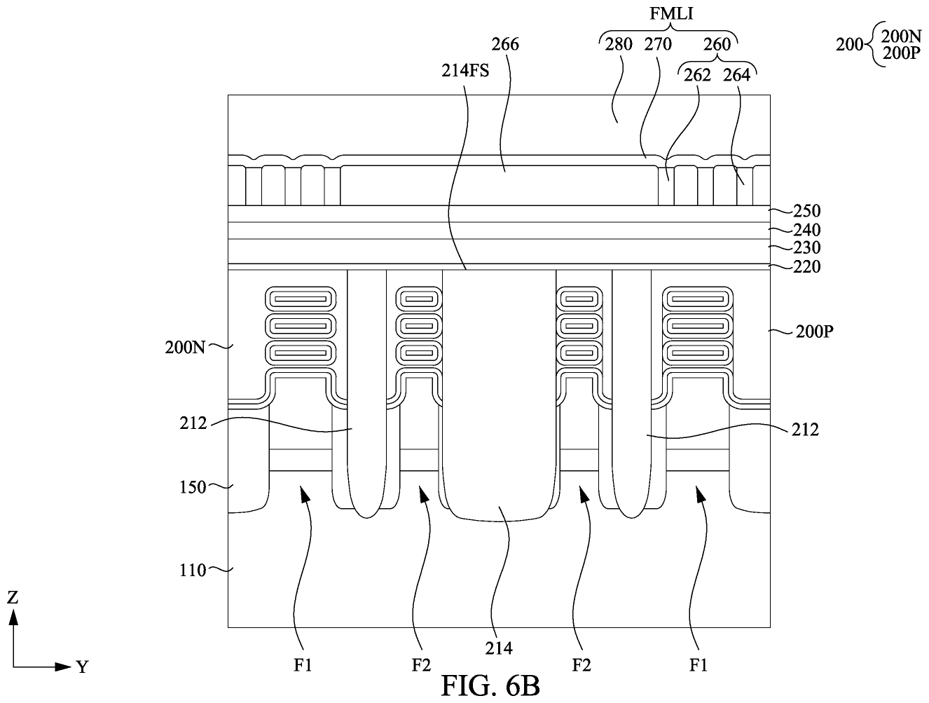

Reference is made to FIGS. 6A-6B. An ESL 220 and an ILD layer 230 are formed over the structure of FIGS. 5A-5D. In some examples, the ESL 220 includes a silicon nitride layer, silicon oxide layer, a silicon oxynitride layer, and/or other suitable materials. In some embodiments, the ILD layer 230 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL 220. The ESL 220 may be formed by plasma-enhanced chemical vapor deposition (PECVD) process and/or other suitable deposition or oxidation processes. The ILD layer 230 may be deposited by a CVD process or other suitable deposition technique. Suitable conductive features can be formed in the ILD layer 230 and the ESL 220 for providing electrical connection to underlying transistors.

An ESL 240 and an ILD layer 250 are formed over the ILD layer 230. In some examples, the ESL 240 includes a silicon nitride layer, silicon oxide layer, a silicon oxynitride layer, and/or other suitable materials. In some embodiments, the ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL 240. The ESL 240 may be formed by plasma-enhanced chemical vapor deposition (PECVD) process and/or other suitable deposition or oxidation processes. The ILD layer 250 may be deposited by a CVD process or other suitable deposition technique. Suitable conductive features can be formed in the ILD layer 250 and the ESL 240 for providing electrical connection to underlying transistors.

A front-side multilayer interconnection (MLI) structure FMLI may be formed over the ILD layer 250. For example, the front-side MLI structure FMLI is formed over the frontsides 212FS and 214FS of the isolation structures 212 and 214. The front-side MLI structure FMLI may include a plurality of front-side metallization layers, such as front-side metallization layers 260 and 280. Etch stop layers (e.g., the etch stop layer 270) may be formed between adjacent two front-side metallization layers (e.g., the front-side metallization layers 260 and 280). The number of front-side metallization layers may vary according to design specifications of the integrated circuit. The front-side metallization layers each comprise a front-side inter-metal dielectric (IMD) layer, one or more horizontal interconnects, such as front-side metal lines, respectively extending horizontally or laterally in the front-side IMD layer, and/or vertical interconnects, such as front-side conductive vias, respectively extending vertically in the front-side IMD layer. In the present embodiments, the bottommost front-side metallization layer 260 includes an IMD layer 262, front-side metal lines 264 extending horizontally or laterally in the IMD layer 262, and a front-side metal feature 266 in the IMD layer 262. The front-side metal feature 266 may vertically overlapping the isolation structure 214. The front-side metal feature 266 may have a height substantially the same as that of the front-side metal lines 264. In some embodiments, the front-side metal feature 266 is configured for receiving an express via extending from a back-side multilayer interconnection (MLI) structure. The front-side metal feature 266 may be referred to as a metal line or pad. The front-side metal feature 266 may be a metal line with a width greater than a width of the front-side metal lines 264 as illustrated in FIG. 6B, for receiving the express via later.

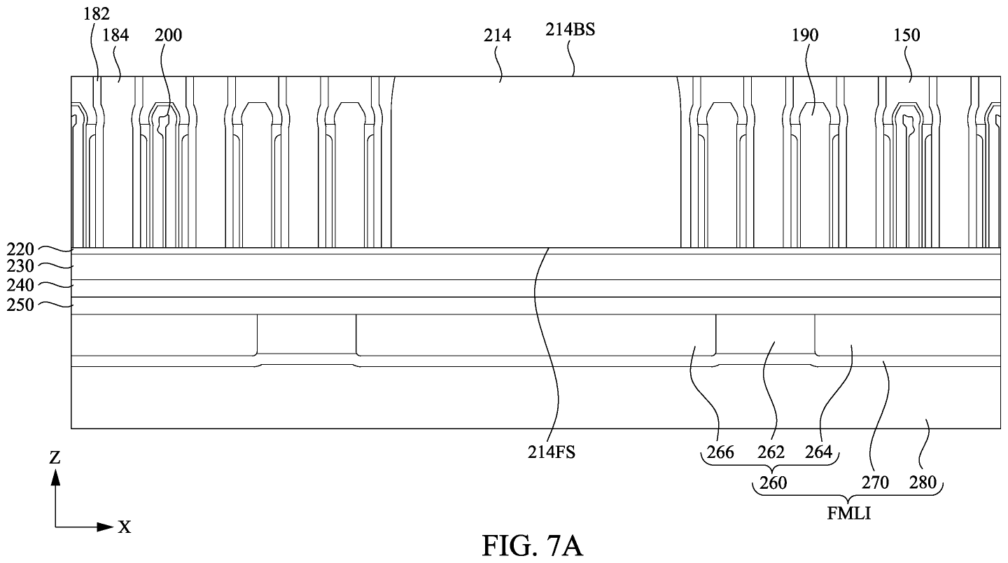

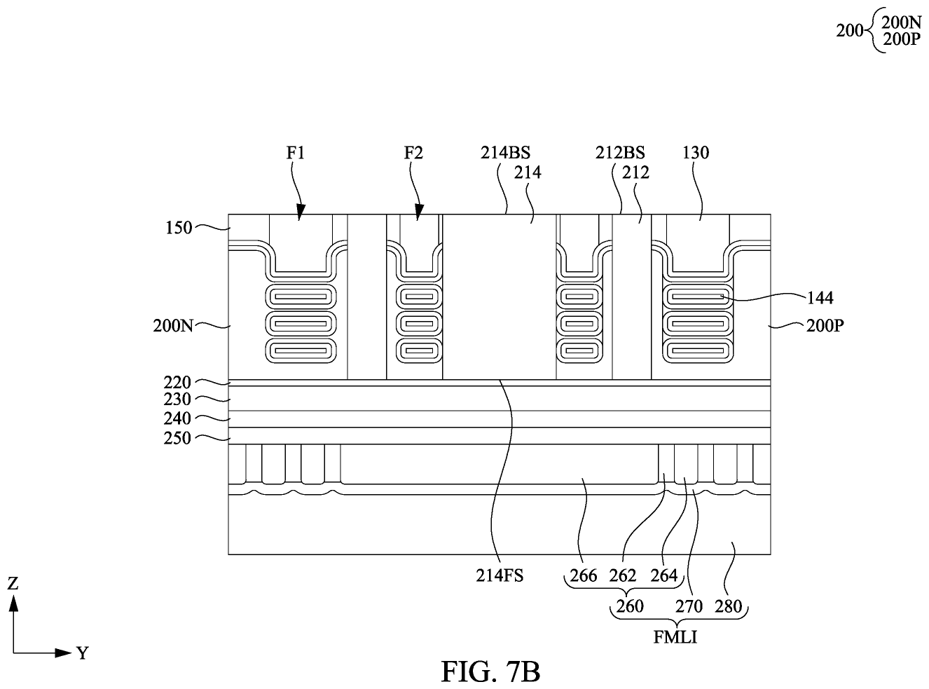

Reference is made to FIGS. 7A-7B. The structure in FIGS. 6A and 6B is turned upside down, and a portion of the substrate 110, the semiconductive etch stop layer 120, portions of the STI structures 150, and portions of the isolation structures 212 and 214 are removed. The removal of these materials may include suitable substrate thinning process, etching process, planarization process (e.g., chemical mechanical polish process), the like, or the combination thereof. The semiconductive etch stop layer 120 may serve as an etch stop layer during the etching process in removal of these materials. After the removal, backsides 212BS and 214BS of the isolation structures 212 and 214 are exposed. The backside 214BS of the isolation structure 214 may be substantially level with the backsides 212BS of the isolation structures 212, the backsides of the STI structures 150, and backsides of the semiconductive layer 130. In some embodiments, the backsides of the isolation structures 190 are not exposed, and remains covered by the STI structures 150 after the removal.

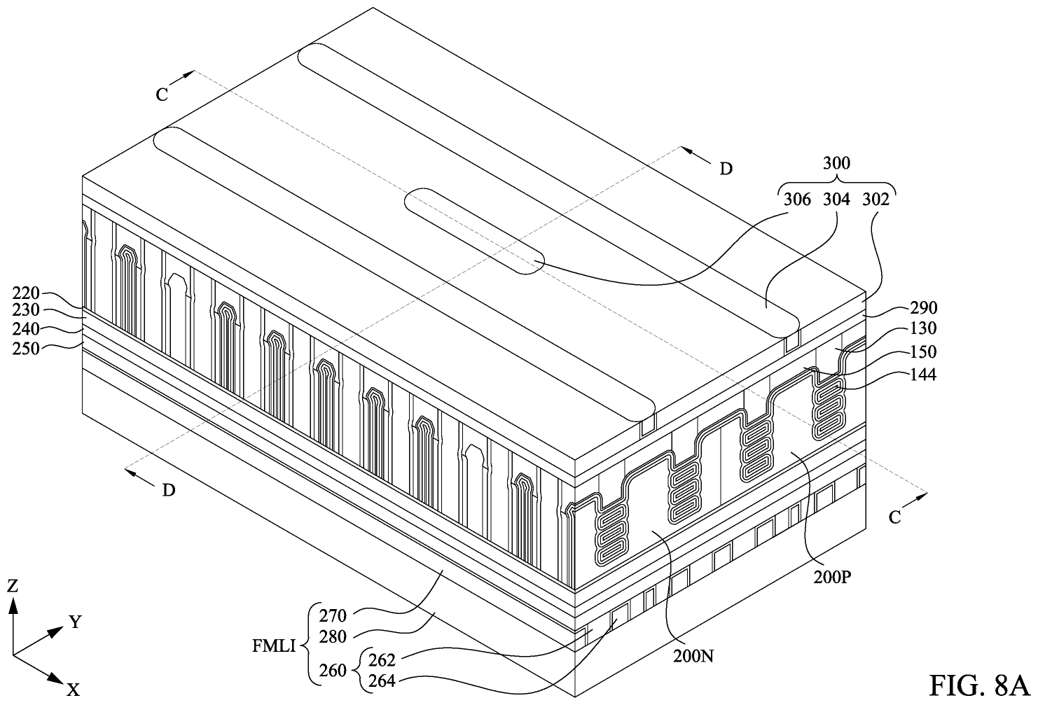

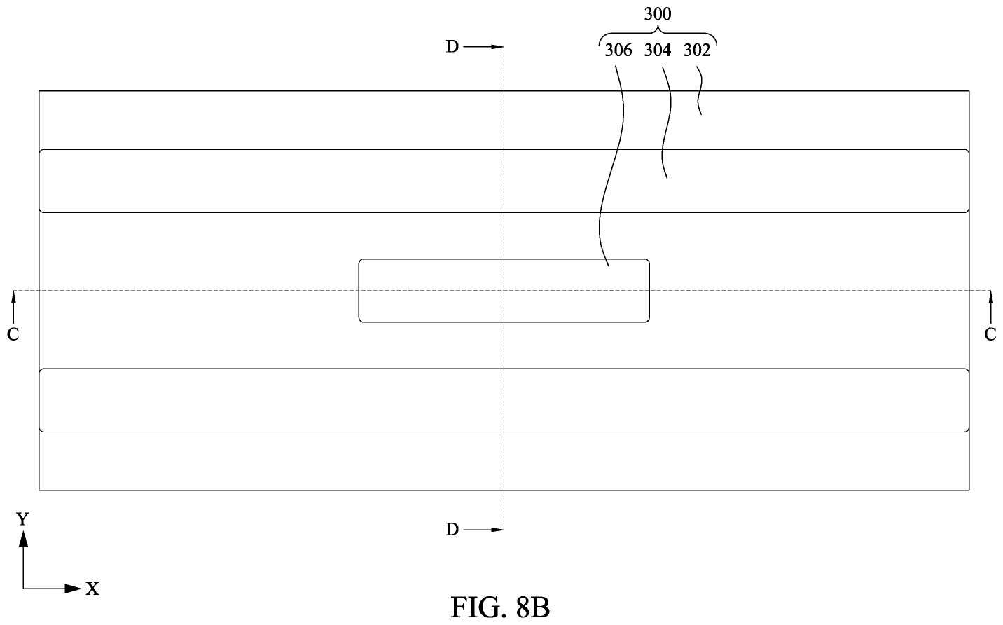

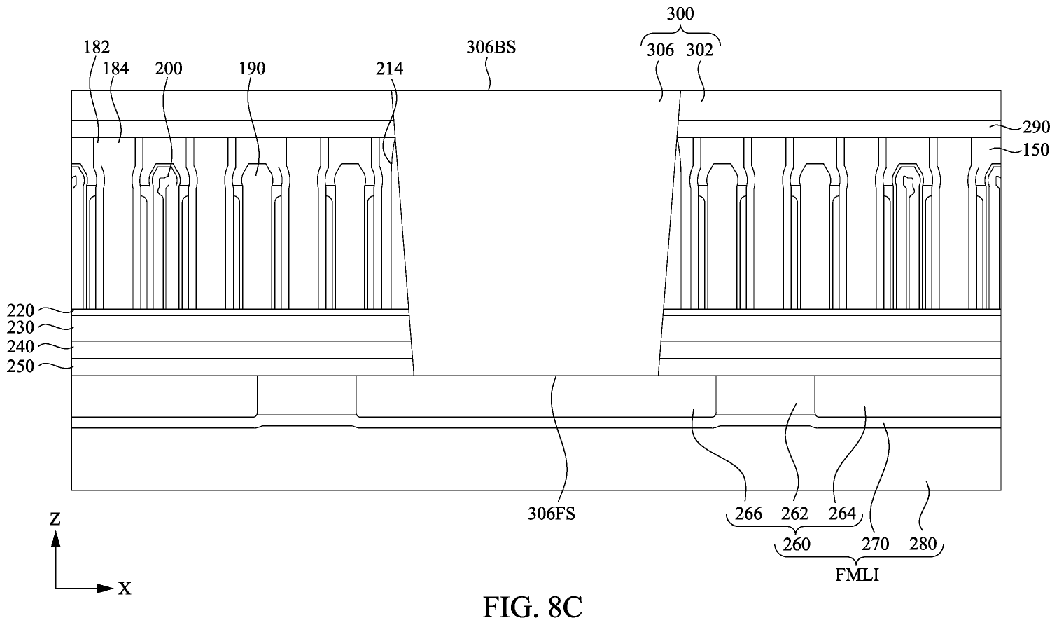

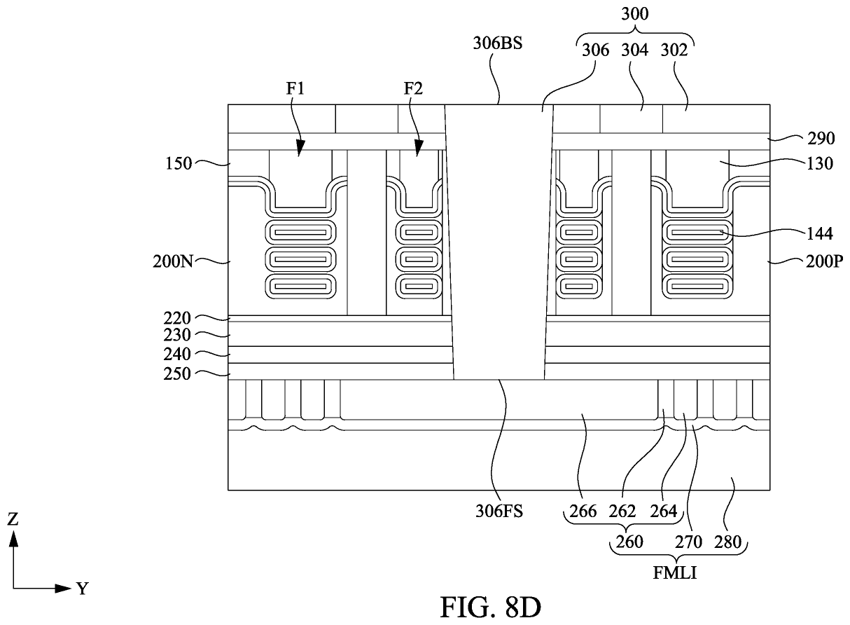

Reference is made to FIGS. 8A-8D. A back-side metallization layer 300 is formed over the structure of FIGS. 7A and 7B. In some embodiments, a back-side MLI structure including plural back-side metallization layers may be formed further over the back-side metallization layer 300. The back-side metallization layer 300 may include an IMD layer 302 and one or more horizontal interconnects, such as back-side metal lines 304, respectively extending horizontally or laterally in the IMD layer 302. In some embodiments, the IMD layer 302 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, an ESL layer 290 may be formed over the structure of FIGS. 7A and 7B, prior to the formation of the back-side metallization layer 300. In some examples, the ESL layer 290 includes a silicon nitride layer, silicon oxide layer, a silicon oxynitride layer, and/or other suitable materials having a different etch selectivity than the IMD layer 302.

In some embodiments, the back-side metallization layer 300 may include a deep conductive via 306 formed in the IMD layer 302, in which the deep conductive via 306 may extend vertically through the ESL layer 290, the isolation structure 214, the layers 220-250, and lands on the front-side metal feature 266. The isolation structure 214 may space the deep conductive via 306 from the high-k/metal gate structure 200. In some embodiments, a top portion of the deep conductive via 306 in the IMD layer 302 is continuously connected with a portion of the deep conductive via 306 in the isolation structure 214. The top portion of the conductive via 306 is in the IMD layer 302 may be laterally aligned with the metal line 304. In some embodiments, the isolation structure 212 is free of a conductive material of the deep conductive via 306. For example, the deep conductive via 306 has a frontside 306FS in contact with the front-side metal feature 266 and a backside 306BS laterally aligned with a backside of the back-side metal lines 304. The deep conductive via 306 may also be referred to as an express via. The deep conductive via 306 may taper toward the front-side MLI structure FMLI. The deep conductive via 306 may have a height greater than that of the high-k/metal gate structures 200. Through the configuration of the deep conductive via 306 connecting the bottommost front-side metallization layer 260 to the back-side metallization layer 300, a direct frontside-to-backside connection is provided for signal routing with lower resistance, lower contact resistance and capacitance, and cost.

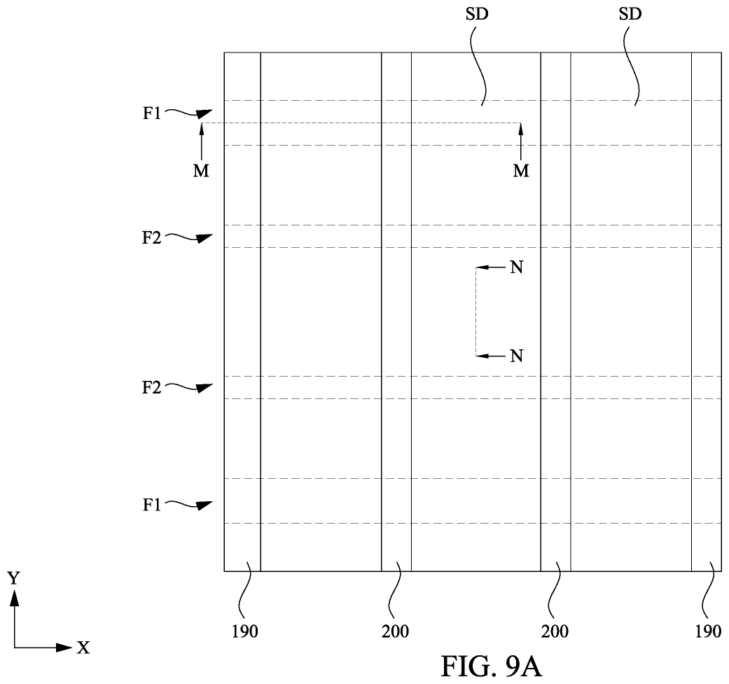

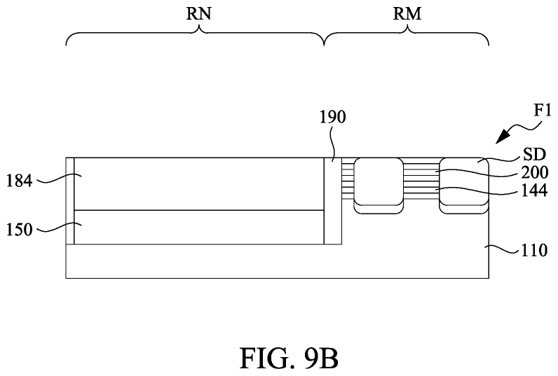

FIGS. 9A-24 illustrate intermediate stages of a method for fabricating an integrated circuit structure in accordance with some embodiments of the present disclosure. FIGS. 9A, 10A, and 23A are top views of the integrated circuit structure. FIGS. 9B, 10B, 11-22, and 23B are cross-sectional views of the integrated circuit structure including a region RN taken along cuts N-N in FIGS. 9A, 10A, and 23A and a region RM taken along cuts M-M in FIGS. 9A, 10A, and 23A. It is understood that additional operations may be provided before, during, and after the operations shown by FIGS. 9A-24, and some of the operations described below can be replaced or eliminated for additional embodiments of the method. The order of the operations/processes may be interchangeable.

Reference is made to FIGS. 9A and 9B. The fins F1 and F2 (e.g., the channel layers 144), the STI structures 150, the ILD layer 184, the isolation structures 190, and the high-k/metal gate structures 200 wrapping around the channel layers 144 are formed over the substrate 110. Formation processes of these elements are similar to those illustrated in FIGS. 1-4D, and not repeated herein.

In some embodiments, prior to the gate replacement process in FIGS. 4A-4D. source/drain recesses are etched in the fins F1 and F2 to expose end sides of the channel layers 144, and then source/drain epitaxial structures SD are formed in the source/drain recesses on the end sides of the channel layers 144. The source/drain epitaxial structures SD may be in contact with the exposed end surfaces of the channel layers 144. In some embodiments, the source/drain epitaxial structures SD may include Ge, Si, GaAs, AlGaAs, SiGe, GaAsP. SiP, or other suitable material. The source/drain epitaxial structures SD may be in-situ doped during the epitaxial process by introducing doping species including: p-type dopants, such as boron or BF2; n-type dopants, such as phosphorus or arsenic; and/or other suitable dopants including combinations thereof. If the source/drain epitaxial structures SD are not in-situ doped, an implantation process (i.e., a junction implant process) is performed to dope the source/drain epitaxial structures SD. The source/drain epitaxial structures SD may be formed by performing an epitaxial growth process that provides an epitaxial material on the exposed surfaces of the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 144. In some embodiments, prior to the formation of the source/drain epitaxial structures SD, isolation layers DL are formed in the source/drain recesses for isolation. The isolation layers DL may include oxide, nitride, or other suitable materials.

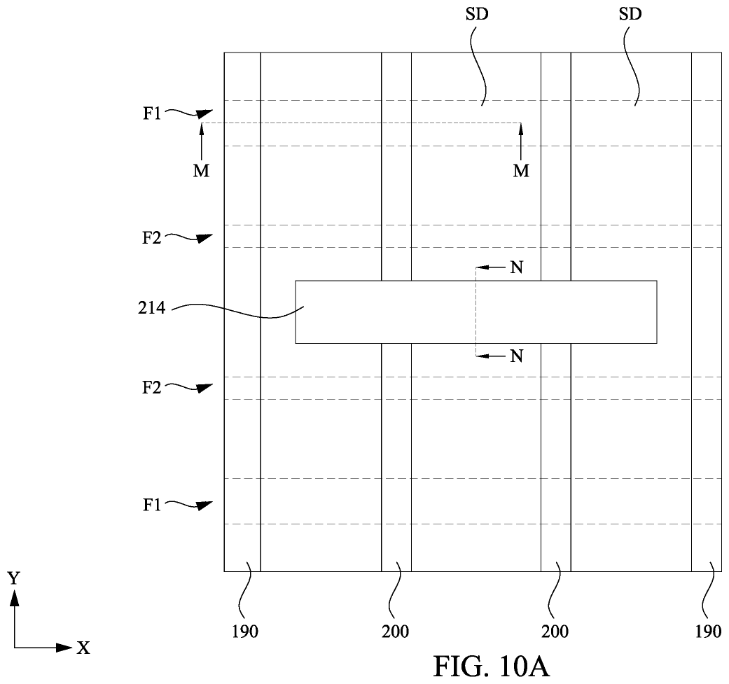

Reference is made to FIGS. 10A and 10B. The isolation structure 214 is formed for cutting the high-k/metal gate structure 200 into separate high-k/metal gate structures. The isolation structure 214 may extend through the ILD layer 184 and the STI structures 150, and reach the substrate 110. Formation processes of the isolation structure 214 are similar to those illustrated in FIGS. 5A-5D, and not repeated herein.

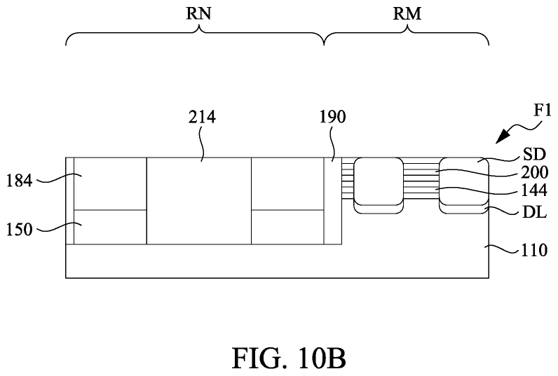

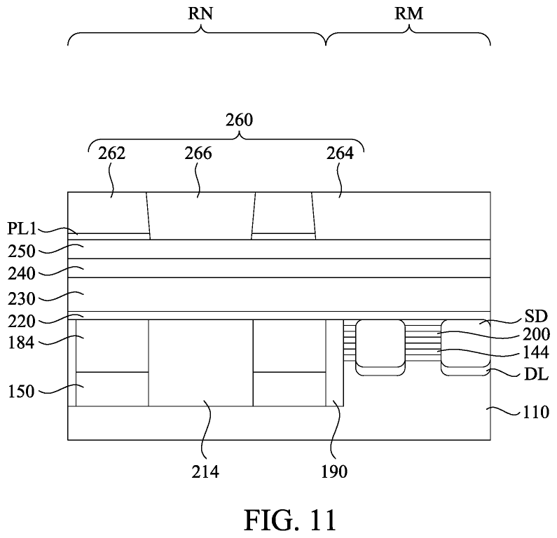

Reference is made to FIG. 11. The ESL 220, the ILD layer 230, the ESL 240, the ILD layer 250, and the front-side metallization layer 260 is formed over the structure of FIGS. 10A and 10B. As aforementioned, the front-side metallization layer 260 includes an IMD layer 262, front-side metal lines 264, and front-side metal feature 266 in the IMD layer 262. Formation processes of these elements are similar to those illustrated in FIGS. 6A and 6B, and not repeated herein. In some embodiments, a protective layer PL1 may be formed over the ILD layer 250, the IMD layer 262 is formed over the protective layer PL1, and the front-side metal lines 264 and the front-side metal feature 266 are formed in the protective layer PL1. The protective layer PL1 may include suitable dielectric materials, such as ceramics. For example, the protective layer PL1 may include metal-containing compounds, such as aluminum oxide, aluminum nitride, the like, or the combination thereof).

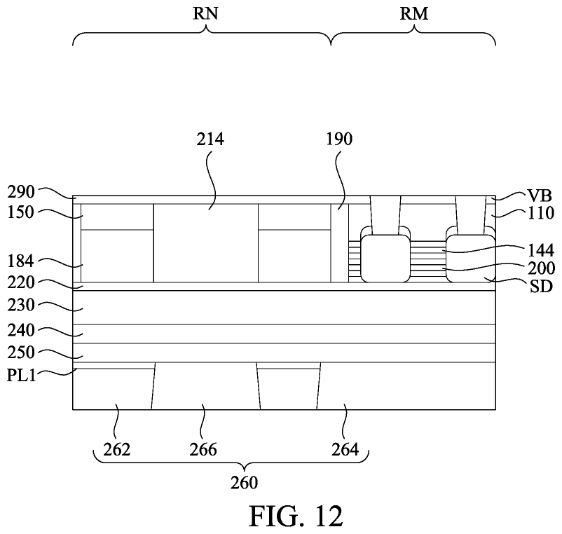

Reference is made to FIG. 12. The structure in FIG. 11 is turned upside down, and a portion of the substrate 110 is removed. The removal of the portion of the substrate 110 may include suitable substrate thinning process, etching process, planarization process (e.g., chemical mechanical polish process), the like, or the combination thereof. After the removal, a backside of the isolation structure 214 and backsides of the STI structures 150 may be exposed. The backside of the isolation structure 214 may be substantially level with the backsides of the STI structures 150. An ESL layer 290 may be formed over the exposed backside of the isolation structure 214 and the exposed backsides of the STI structures 150. In some examples, the ESL layer 290 includes a silicon nitride layer, silicon oxide layer, a silicon oxynitride layer, and/or other suitable materials having a different etch selectivity than the IMD layer 302.

Backside contact plugs VB are formed for providing electrical connection to the source/drain epitaxial structures SD. For example, one or more etching processes are performed to form contact openings by removing portions of the substrate 110 and the ESL layer 290. The contact openings may expose backsides of the source/drain epitaxial structures SD. Subsequently, contact materials may be deposited into the contact openings. The contact materials may include a barrier layer (e.g., TiN, TaN, or combinations thereof) and a fill metal (e.g., W, Co, Ru, Al, Cu, or other suitable materials.). After the deposition of the contact materials, a planarization process, such as a chemical mechanical polish (CMP) process, may be then performed to remove an excess of the contact materials outside the contact openings. Remaining portions of the contact materials in the contact openings form the backside contact plugs VB. In some embodiments, prior to the deposition of the contact materials, dielectric liners are formed in the contact opening and exposing the backsides of the source/drain epitaxial structures SD. The dielectric liners may space and electrically isolating the backside contact plugs VB from the substrate 110.

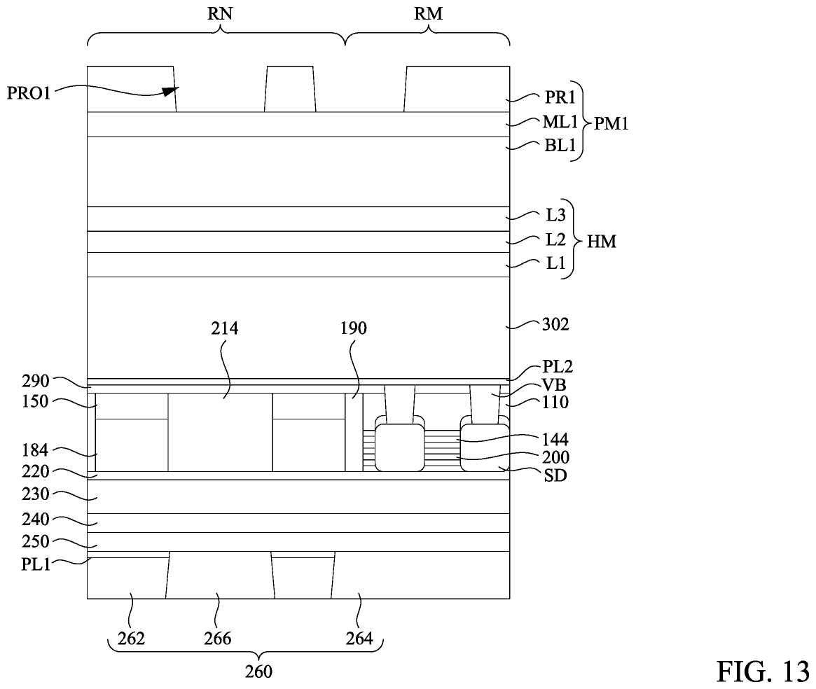

FIGS. 13-23B illustrates the formation process of the back-side metallization layer 300 including the IMD layer 302, the front-side metal lines 304, and the deep conductive via 306. Referring to FIG. 13, an IMD layer 302 is deposited over the structure of FIG. 12. The IMD layer 302 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. Prior to the deposition of the IMD layer 302, a protective layer PL2 is formed over the ESL layer 290 and the backside contact plugs VB. The protective layer PL2 may include suitable dielectric materials, such as ceramics. For example, the protective layer PL2 may include metal-containing compounds, such as aluminum oxide, aluminum nitride, the like, or the combination thereof).

A hard mask layer HM is formed over the IMD layer 302. In some embodiments, the hard mask layer HM is a multi-layer structure. For example, the hard mask layer HM includes a dielectric layer L1, a metal-containing layer L2, and a dielectric layer L3. The dielectric layers L1 and L3 may be TEOS oxide layers, and the metal-containing layer L2 may be a carbon-doped tungsten (WDC) layer.

A tri-layer photoresist structure PM1 is formed over the hard mask layer HM. The tri-layer photoresist structure PM1 includes a bottom layer BL1, a middle layer ML1, and a top layer PR1. In some embodiments, the bottom layer BL1 is a bottom anti-reflective coating (BARC) layer which is used to reduce reflection during the photolithography process. In some embodiments, the bottom layer BL1 is made of nitrogen-free material, such as silicon rich oxide, or silicon oxycarbide (SiOC). In some embodiments, the middle layer ML1 is made of silicon-based material, such as silicon nitride, silicon oxynitride or silicon oxide. The top layer PR1 may be a positive photoresist layer or a negative photoresist layer. The top layer PR1 is formed with a pattern defining metal lines by suitable photolithography process. The photolithography process may include forming a photoresist layer (not shown) over the middle layer ML1, exposing the photoresist to a pattern, performing post-exposure bake processes, and developing the resist to form a patterned mask including the resist. For example, the top layer PR1 include openings PRO1, and one of which is directly above the isolation structure 214.

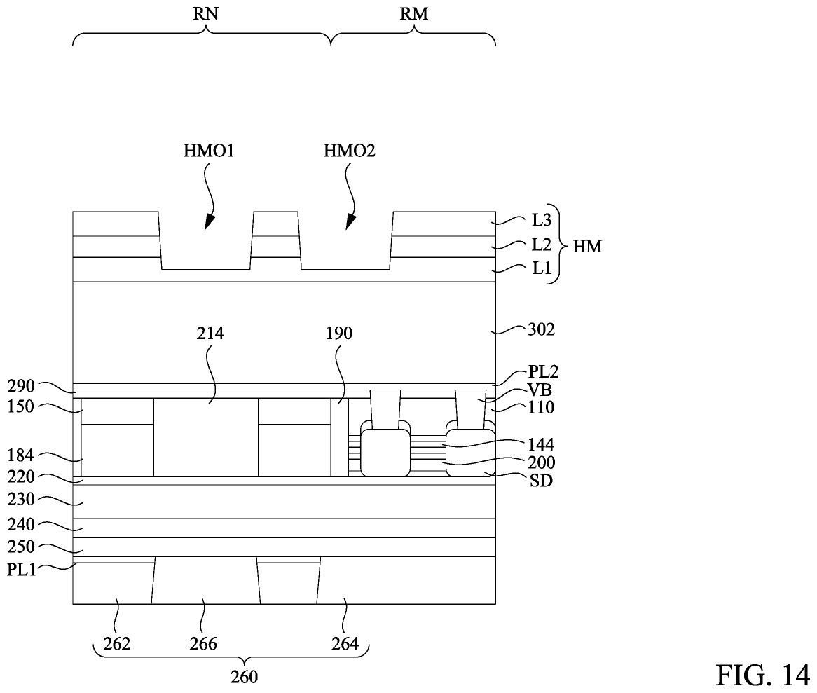

Reference is made to FIG. 14. An etching process is performed to pattern the hard mask layer HM by using the tri-layer photoresist structure PM1 (referring to FIG. 13) as an etch mask. The etching process may include one or more suitable dry etch processes. After the etching process, the patterned hard mask layer HM may include opening/trenches HMO1 and HMO2. The opening/trenches HMO1 may be directly above the isolation structure 214. The opening/trenches HMO2 may be directly above the backside contact plugs VB. The tri-layer photoresist structure PM1 (referring to FIG. 13) may be removed by a suitable removal process (e.g., etching process).

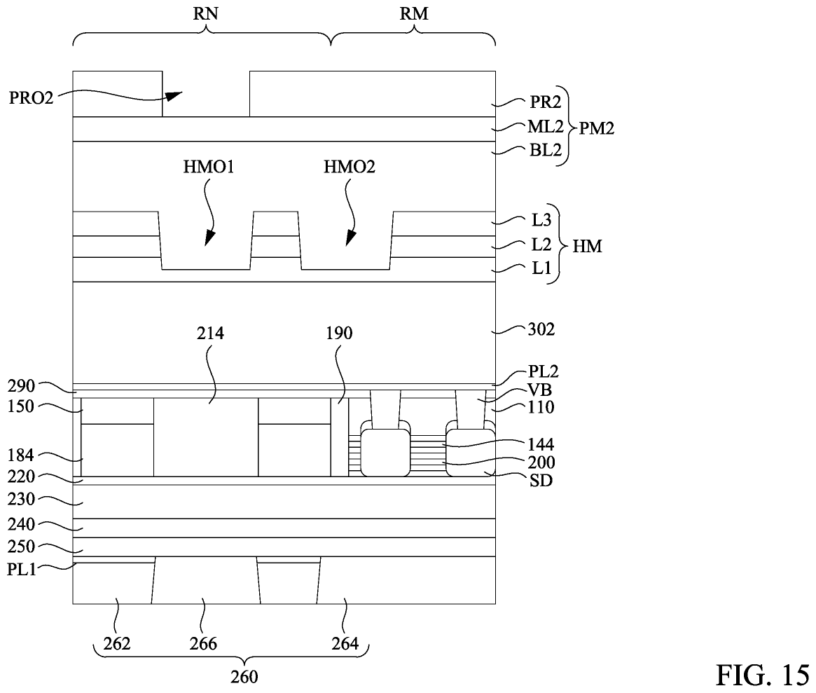

Reference is made to FIG. 15. A tri-layer photoresist structure PM2 is formed over the hard mask layer HM. The tri-layer photoresist structure PM2 includes a bottom layer BL2, a middle layer ML2, and a top layer PR2. In some embodiments, the bottom layer BL2 is a bottom anti-reflective coating (BARC) layer which is used to reduce reflection during the photolithography process. In some embodiments, the bottom layer BL2 is made of nitrogen-free material, such as silicon rich oxide, or silicon oxycarbide (SiOC). In some embodiments, the middle layer ML2 is made of silicon-based material, such as silicon nitride, silicon oxynitride or silicon oxide. The top layer PR2 may be a positive photoresist layer or a negative photoresist layer. The top layer PR2 is formed with a pattern defining the express via by suitable photolithography process. The photolithography process may include forming a photoresist layer (not shown) over the middle layer ML2, exposing the photoresist to a pattern, performing post-exposure bake processes, and developing the resist to form a patterned mask including the resist. For example, the top layer PR2 include an opening PRO2 directly above the isolation structure 214 and the opening/trenches HMO1, and the top layer PR2 covers the opening/trenches HMO2.

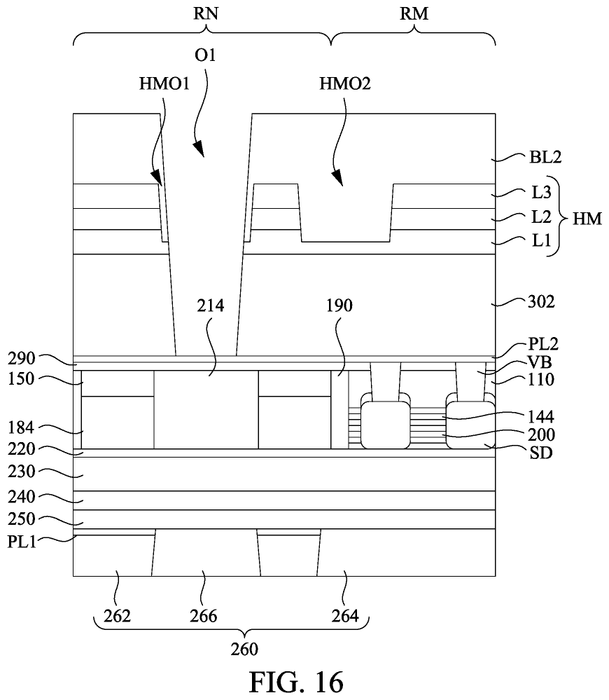

Reference is made to FIG. 16. An etching process is performed to form an opening O1 by using the tri-layer photoresist structure PM2 (referring to FIG. 14) as an etch mask. The opening O1 may extend through the opening/trenches HMO1 and vertically overlapping the isolation structure 214. The etching process may include one or more suitable dry etch processes. After the etching process, the opening O1 is formed in the bottom layer BL2 of the hard mask layer HM, the layer L1, and the IMD layer 302, and expose a top surface of the protective layer PL2. The protective layer PL2 may serve as an etch stop layer during the etching process. The top layer PR2 and the middle layer ML2 of the tri-layer photoresist structure PM2 (referring to FIG. 15) may be removed by a suitable removal process (e.g., etching process).

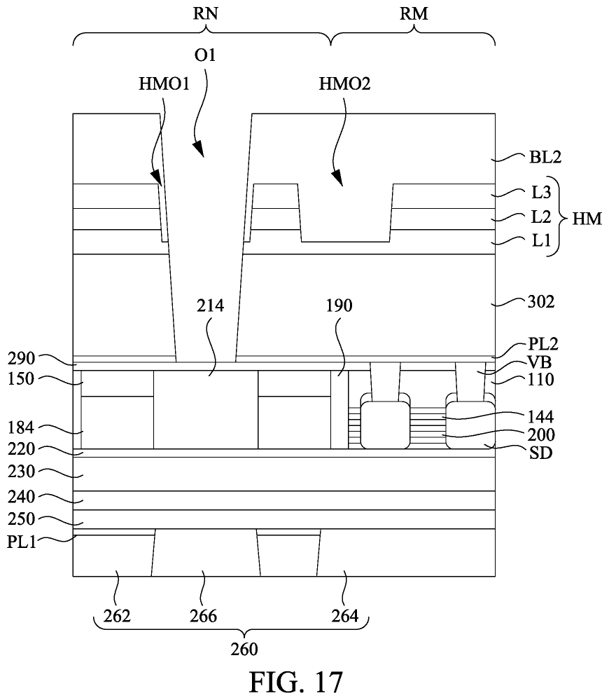

Reference is made to FIG. 17. With the bottom layer BL2 covering the opening/trenches HMO2, a wet removal process is performed to remove a portion of the protective layer PL2 exposed by the opening O1.

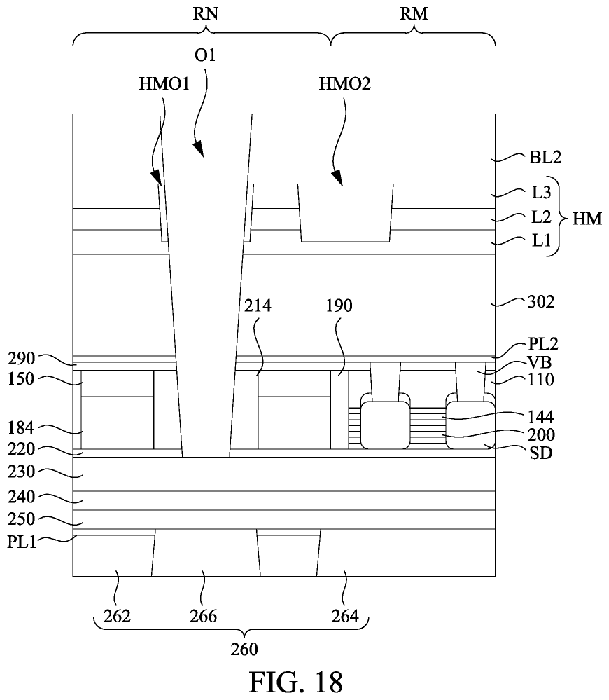

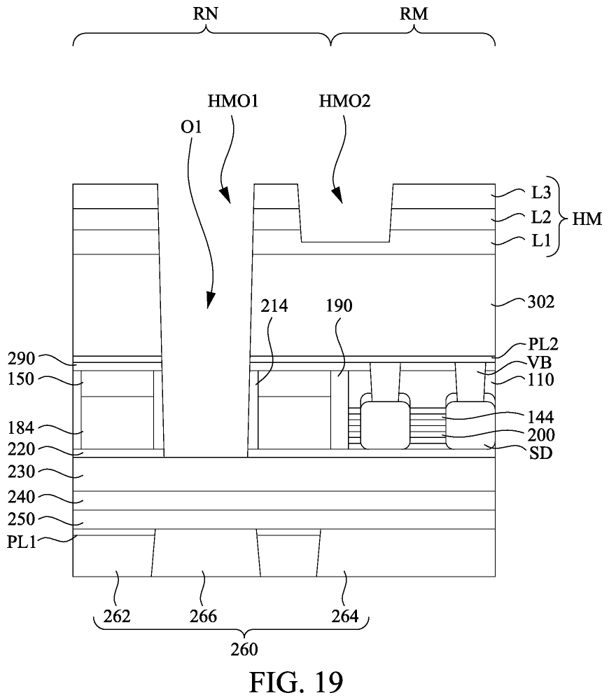

Reference is made to FIG. 18. With the bottom layer BL2 covering the opening/trenches HMO2, a dry etching process is performed to deepen the opening O1, such that the opening O1 extends through the isolation structure 214 and reach the ESL 220. In the present embodiments, the opening O1 does not reach the ILD layer 230 underlying the ESL 220. In some alternative embodiments, the opening O1 may extend through the ESL 220 and reach the ILD layer 230. After the deepening process, the bottom layer BL2 can be removed by suitable ashing process, as illustrated in FIG. 19.

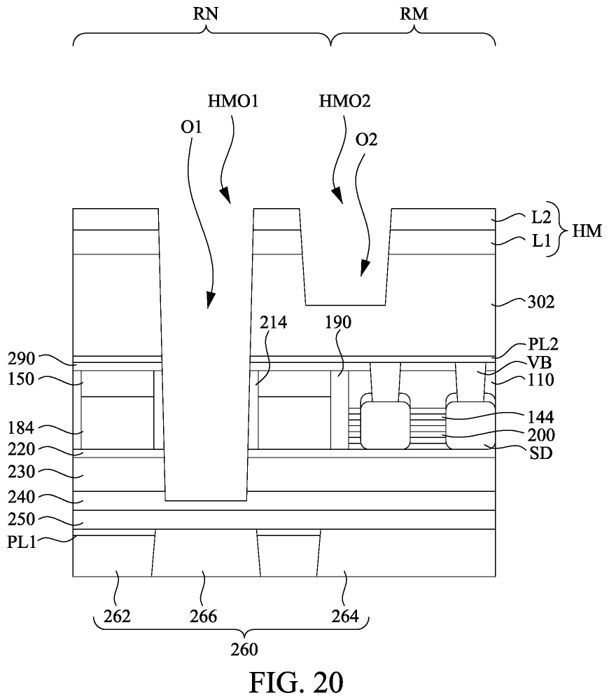

Reference is made to FIG. 20. An etching process is performed to form an opening O2 and further deepen the opening O1 by using the tri-layer photoresist structure PM2 (referring to FIG. 19) as an etch mask. The opening O2 may extend through the opening/trenches HMO2. The etching process may include one or more suitable dry etch processes. After the etching process, the opening O1 is formed in the IMD layer 302, and the opening O2 extends downwards through the ESL 220 and the ILD layer 230 and reach the ESL 240.

In some embodiments, the wet removal process and/or the etching processes illustrated in FIGS. 17-20 may enlarge a width of the opening O1, such that a sidewall of the opening O1 may coincide a sidewall of the opening/trench HMO1 in the hard mask layer HM. The opening/trenches HMO1 and HMO2 may be referred to as a top portion of the openings O1 and O2 in some embodiments. In some alternative embodiments, the hard mask layer HM may be removed after the formation of the opening O2.

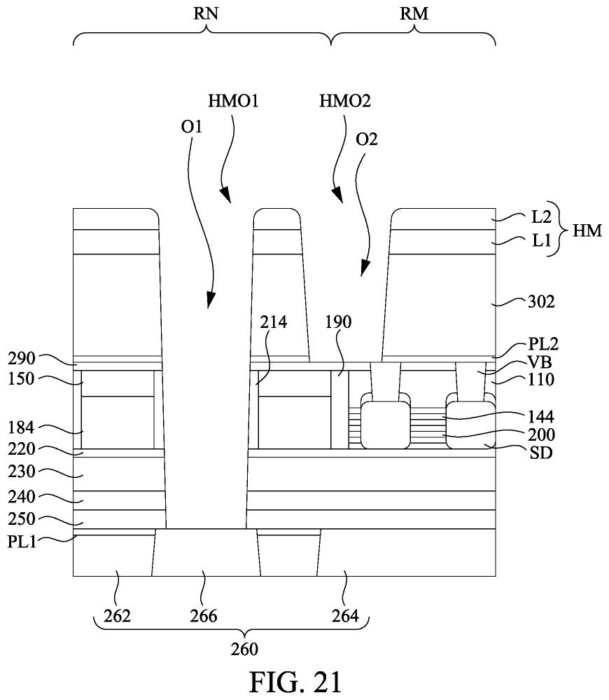

Reference is made to FIG. 21. A liner removal process is performed to round top corners of the openings O1 and O2 (e.g., the opening/trenches HMO1 and HMO2 in the hard mask layer HM, or the openings O1 and O2 in the IMD layer 302 if the hard mask layer HM is already removed) and further deepen the openings O1 and O2. The liner removal process may include suitable etch process (e.g., dry etch process) and wet cleaning process. The corner rounding process is beneficial for subsequent gap fill process (e.g., filling the openings O1 and O2 with a conductive layer CL). The liner removal process may deepen the opening O1 by removing a portion of the ESL 240 and the ILD layer 250 below the opening O1 (referring to FIG. 20), such that the opening O1 may expose the front-side metal feature 266. The liner removal process may deepen the opening O2 by removing a portion of the IMD layer 302 and the protective layer PL2 below the opening O2 (referring to FIG. 20), such that the opening O2 may expose the backside contact plugs VB.

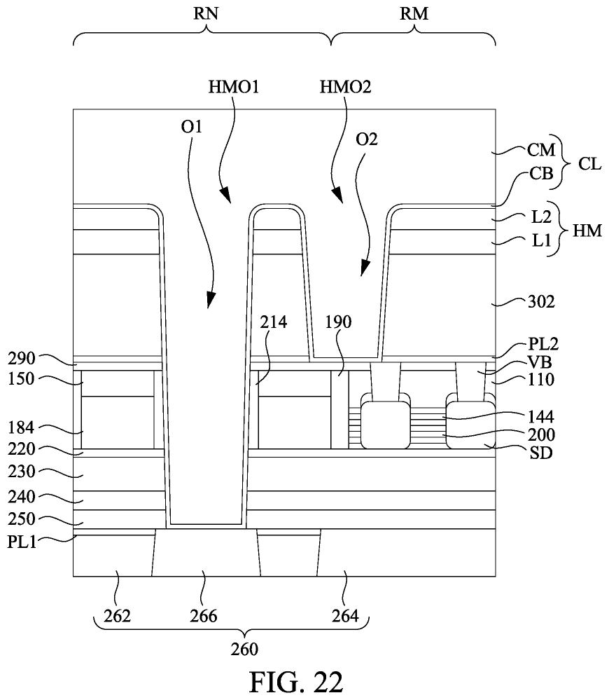

Reference is made to FIG. 22. A conductive material CL is deposited over the structure of FIG. 21, for example, by CVD. PVD. ALD, or other suitable techniques. The conductive material CL may fill the openings 01 and 02. The conductive material CL may include a barrier metal layer CB and a fill metal layer CM. The barrier metal layer CB may include TiN, TaN, the like, or the combination thereof. The fill metal layer CM may include copper, tungsten, aluminum, the like, or the combination thereof.

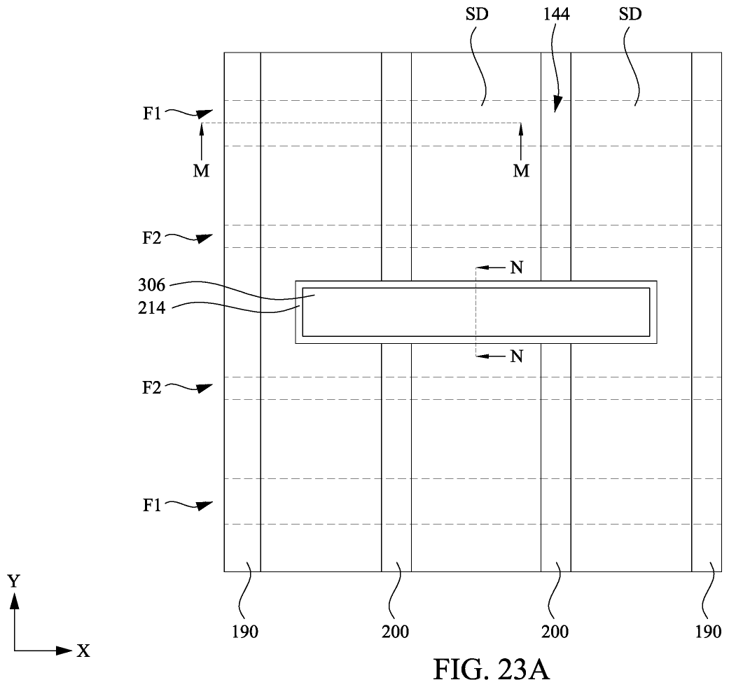

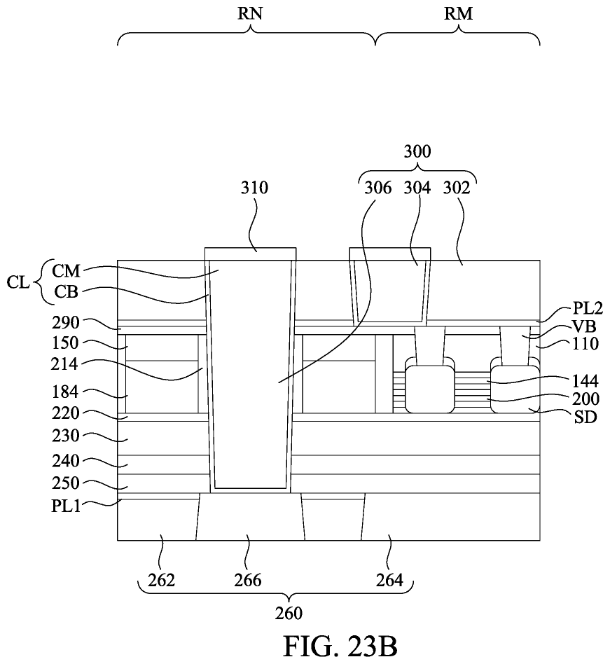

Reference is made to FIGS. 23A and 23B. A planarization process is performed to remove portions of the conductive material CL outside the openings O1 and O2. A remaining portion of the conductive material CL in the opening O1 is referred to as a deep conductive via 306. The deep conductive via 306 is in contact with the front-side metal feature 266, thereby providing a direct frontside-to-backside connection for signal routing. A remaining portion of the conductive material CL in the opening O2 is referred to as a metal line 304. The metal line 304 is in contact with the backside contact plug VB, thereby establishing electrical connection between the source/drain epitaxial structures SD and the back-side metallization layer 300.

After the planarization process, metal cap layers 310 may be selectively deposited over the metal line 304 and the deep conductive via 306 for enhancing the reliability. The metal cap layers 310 may include suitable metal capping material, such as cobalt. The selective deposition process may include deposit the metal capping material (e.g., cobalt) over surfaces of the copper layer CM of the metal line 304 and the deep conductive via 306, while little or no metal capping material (e.g., cobalt) is deposited over surfaces of the IMD layer 302.

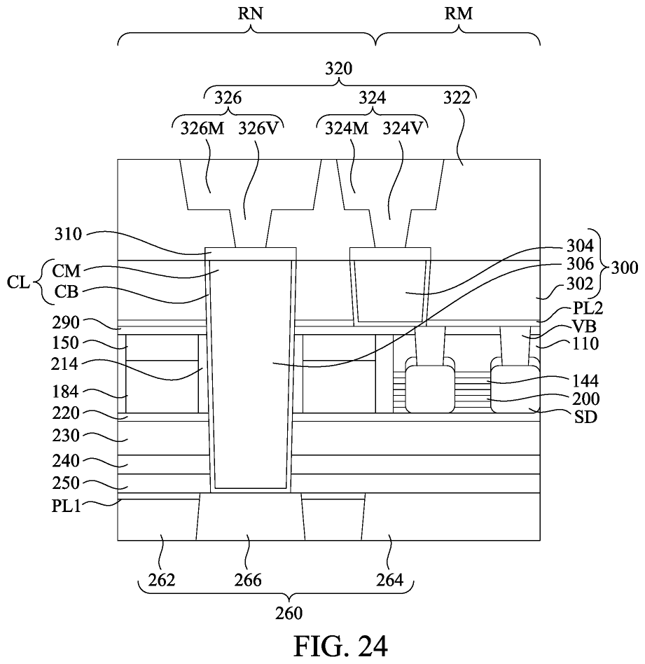

Reference is made to FIG. 24. After the formation of the metal cap layers 310, a back-side MLI structure including plural back-side metallization layers may be formed further over the back-side metallization layer 300. The back-side metallization layer 320 may include an IMD layer 322 and metal features 324 and 326 in the IMD layer 322. The metal features 324 and 326 may include one or more horizontal interconnects, such as metal lines 324M and 326M, respectively extending horizontally or laterally in the front-side IMD layer, and/or vertical interconnects, such as conductive vias 324V and 326B, respectively extending vertically in the IMD layer 322. One of the metal cap layers 310 may be located between the metal line 304 and the metal feature 324, and another one of the metal cap layers 310 may be located between the deep conductive via 306 and the metal feature 326. The deep conductive via 306 may connect the front-side metal feature 266 to the back-side metal feature 326.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that an express via (EV) is designed to provide a direct frontside-to-backside connection for signal routing with lower resistance, low capacitance, and low cost. Another advantage is that the express via makes the signal transmission path between frontside and backside experiences less heterointerfaces, thereby lowering contact resistance.

In some embodiments of the present disclosure, a method includes forming a gate structure over a semiconductor substrate; forming a source/drain epitaxial structure adjacent a side of the gate structure; forming a first isolation structure in the gate structure, wherein the first isolation structure spaces apart a first portion of the gate structure from a second portion of the gate structure from a top view; forming a front-side metallization layer over a frontside of the first isolation structure, wherein the front-side metallization layer comprises a front-side metal feature overlapping the first isolation structure; depositing a dielectric layer over a backside of the first isolation structure; and forming a conductive via in the dielectric layer and the first isolation structure, wherein the conductive via is in contact with the front-side metal feature.

In some embodiments of the present disclosure, a method includes forming an epitaxial stack over a semiconductor substrate, wherein the epitaxial stack comprises a sacrificial layer and a channel layer over the sacrificial layer; patterning the epitaxial stack into a fin; forming a dummy gate structure over the fin; replacing the dummy gate structure and the sacrificial layer with a metal gate structure surrounding the channel layer; forming an isolation structure in the metal gate structure, wherein the isolation structure spaces apart a first portion of the metal gate structure from a second portion of the metal gate structure from a top view; and forming a conductive via in the isolation structure, wherein a height of the conductive via is greater than a height of the metal gate structure.

In some embodiments of the present disclosure, an IC structure includes a transistor comprising a channel layer, a gate structure surrounding the channel layer, and a source/drain epitaxial structure adjacent a side of the gate structure; a first isolation structure in the gate structure, wherein the first isolation structure spaces apart a first portion of the gate structure from a second portion of the gate structure from a top view; a front-side metallization layer over a frontside of the first isolation structure, wherein the front-side metallization layer comprises a front-side metal feature overlapping the first isolation structure; a back-side metallization layer over a backside of the first isolation structure; and a conductive via extending from the back-side metallization layer to the front-side metal feature through the first isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a gate structure over a semiconductor substrate;
forming a source/drain epitaxial structure adjacent a side of the gate structure;
forming a first isolation structure in the gate structure, wherein the first isolation structure spaces apart a first portion of the gate structure from a second portion of the gate structure from a top view;
forming a front-side metallization layer over a frontside of the first isolation structure, wherein the front-side metallization layer comprises a front-side metal feature overlapping the first isolation structure;
depositing a dielectric layer over a backside of the first isolation structure; and
forming a conductive via in the dielectric layer and the first isolation structure, wherein the conductive via is in contact with the front-side metal feature.

2. The method of claim 1, wherein forming the conductive via comprises:
etching an opening in the dielectric layer, wherein the opening overlaps the first isolation structure;
deepening the opening such that the opening extends through the first isolation structure and exposes the front-side metal feature; and
depositing a conductive material into the deepened opening.

3. The method of claim 1, further comprising:
forming a contact plug on a backside of the source/drain epitaxial structure; and
forming a conductive line in the dielectric layer, wherein the conductive line is in contact with a backside of the contact plug.

4. The method of claim 3, wherein a portion of the conductive via is at a same level height as the conductive line.

5. The method of claim 3, wherein forming the conductive via and forming the conductive line comprises:
etching a first opening in the dielectric layer and the first isolation structure;
etching a second opening in the dielectric layer and exposing the backside of the contact plug, wherein etching the second opening is performed such that the first opening is deepened to expose the front-side metal feature; and
depositing a conductive material into the first opening and the second opening.

6. The method of claim 1, wherein a height of the conductive via is greater than a height of the gate structure.

7. The method of claim 1, further comprising:
forming a second isolation structure in the gate structure, wherein the second isolation structure spaces apart the second portion of the gate structure from a third portion of the gate structure, and forming the conductive via is performed such that the second isolation structure is free of a material of the conductive via.

8. The method of claim 7, wherein a length of the second isolation structure along a direction perpendicular to a lengthwise direction of the gate structure is greater than a length of the first isolation structure along the direction from a top view.

9. The method of claim 7, wherein a width of the second isolation structure along a lengthwise direction of the gate structure is less than a width of the first isolation structure along the lengthwise direction of the gate structure from a top view.

10. The method of claim 1, wherein a first portion of the conductive via in the dielectric layer is formed of a same material composition as a second portion of the conductive via in the first isolation structure.

11. A method, comprising:
forming an epitaxial stack over a semiconductor substrate, wherein the epitaxial stack comprises a sacrificial layer and a channel layer over the sacrificial layer;
patterning the epitaxial stack into a fin;
forming a dummy gate structure over the fin;
replacing the dummy gate structure and the sacrificial layer with a metal gate structure surrounding the channel layer;
forming an isolation structure in the metal gate structure, wherein the isolation structure spaces apart a first portion of the metal gate structure from a second portion of the metal gate structure from a top view; and
forming a conductive via in the isolation structure, wherein a height of the conductive via is greater than a height of the metal gate structure.

12. The method of claim 11, further comprising:
removing a portion of the semiconductor substrate to expose a backside of the isolation structure prior to forming the conductive via.

13. The method of claim 11, further comprising:
forming shallow trench isolation (STI) structures around the fin, wherein forming the isolation structure is performed such that the isolation structure extends through the STI structures.

14. The method of claim 11, wherein the first portion of the metal gate structure comprises an n-type work function metal layer, and the second portion of the metal gate structure comprises a p-type work function metal layer.

15. An integrated circuit (IC) structure, comprising:
a transistor comprising a channel layer, a gate structure surrounding the channel layer, and a source/drain epitaxial structure adjacent a side of the gate structure;
a first isolation structure in the gate structure, wherein the first isolation structure spaces apart a first portion of the gate structure from a second portion of the gate structure from a top view;
a front-side metallization layer over a frontside of the first isolation structure, wherein the front-side metallization layer comprises a front-side metal feature overlapping the first isolation structure;
a back-side metallization layer over a backside of the first isolation structure; and
a conductive via extending from the back-side metallization layer to the front-side metal feature through the first isolation structure.

16. The IC structure of claim 15, wherein the conductive via is spaced apart from the gate structure by the first isolation structure.

17. The IC structure of claim 15, wherein the back-side metallization layer comprises a dielectric layer and a metal line in the dielectric layer, wherein a portion of the conductive via is in the dielectric layer and at a same level height as the metal line.

18. The IC structure of claim 15, wherein the conductive via tapers toward the front-side metallization layer.

19. The IC structure of claim 15, wherein a height of the conductive via is greater than a height of the gate structure.

20. The IC structure of claim 15, further comprises:
a second isolation structure in the gate structure, wherein the second isolation structure spaces apart the second portion of the gate structure from a third portion of the gate structure, and the second isolation structure is free of a material of the conductive via.
